(19) United States
(12) Patent Application Publication
(10) Pub. No.: US 2025/0295007 A1
(43) Pub. Date: Sep. 18, 2025

(54) DISPLAY PANEL AND METHOD OF MANUFACTURING THE SAME

(71) Applicant: Samsung Display Co., Ltd., Yongin-si (KR)

(72) Inventor: Hee Jun YANG, Yongin-si (KR)

(21) Appl. No.: 18/990,993

(22) Filed: Dec. 20, 2024

(30) Foreign Application Priority Data
Mar. 15, 2024 (KR) 10-2024-0036706

(51) Int. Cl. H10K 59/80; H10K 59/12; H10K 59/122

(52) U.S. Cl. CPC H10K 59/873; H10K 59/1201; H10K 59/122

(57) ABSTRACT

A display panel includes a circuit element layer including a transistor, a common electrode on the circuit element layer, a conductive barrier wall on the common electrode and defining an outer barrier wall opening and an inner barrier wall opening, a barrier insulating layer on the conductive barrier wall, a first electrode on the barrier insulating layer and in the inner barrier wall opening and electrically connected to the transistor, a light emitting pattern on the first electrode and covering a portion of the conductive barrier wall and the barrier insulating layer, and a second electrode covering the light emitting pattern and electrically connected to the conductive barrier wall. The inner barrier wall opening of the conductive barrier wall overlaps a center of the light emitting pattern.

### CROSS-REFERENCE TO RELATED APPLICATION

The present application claims priority to and the benefit of Korean Patent Application No. 10-2024-0036706, filed on Mar. 15, 2024, in the Korean Intellectual Property Office, the entire disclosure of which is incorporated herein by reference.

### BACKGROUND

### 1. Field

Embodiments of the present disclosure relate to a display panel and a method of manufacturing the same. For example, embodiments of the present disclosure relate to a display panel with improved display quality and a method of manufacturing the display panel.

### 2. Description of Related Art

Display devices that provide images to users, such as television sets, monitors, smart phones, and/or tablet computers, may include a display panel to display the images. Various types (kinds) of display panels, such as liquid crystal display panels, organic light emitting display panels, electrowetting display panels, and/or electrophoretic display panels, are being developed.

An organic light emitting display panel may include an anode, a cathode, and a light emitting pattern. The light emitting pattern may be divided into portions arranged in light emitting areas, and the cathode may provide a common voltage to each of the light emitting areas.

### SUMMARY

Aspects of one or more embodiments of the present disclosure are directed toward a display panel that includes a light emitting element formed without using a metal mask and having improved display quality.

Aspects of one or more embodiments of the present disclosure are directed toward a method of manufacturing the display panel.

Additional aspects will be set forth in part in the description which follows and, in part, will be apparent from the description, or may be learned by practice of the presented embodiments of the disclosure.

One or more embodiments of the present disclosure provide a display panel including a circuit element layer including a transistor, a common electrode on the circuit element layer, a conductive barrier wall on the common electrode and defining an outer barrier wall opening and an inner barrier wall opening, a barrier insulating layer on the conductive barrier wall, a first electrode on the barrier insulating layer and in the inner barrier wall opening and electrically connected to the transistor, a light emitting pattern on the first electrode and covering a portion of the conductive barrier wall and the barrier insulating layer, and a second electrode covering the light emitting pattern and electrically connected to the conductive barrier wall. The inner barrier wall opening of the conductive barrier wall overlaps a center of the light emitting pattern.

In one or more embodiments, the inner barrier wall opening may have a polygonal shape.

In one or more embodiments, the inner barrier wall opening may have a circular shape.

In one or more embodiments, the conductive barrier wall may include a first barrier wall layer on the common electrode and a second barrier wall layer on the first barrier wall layer.

In one or more embodiments, the first barrier wall layer may include a first inner side surface, the second barrier wall layer may include a second inner side surface, and the first inner side surface and the second inner side surface may define the inner barrier wall opening and may be aligned with each other.

In one or more embodiments, the outer barrier wall opening may include a first area defined by a first outer side surface of the first barrier wall layer and a second area defined by a second outer side surface of the second barrier wall layer, a length in a first direction of the first area may be greater than a length in the first direction of the second area, and the first direction may be normal (e.g., perpendicular) to a thickness direction of the circuit element layer.

In one or more embodiments, the light emitting pattern may cover at least a portion of the second outer side surface of the second barrier wall layer.

In one or more embodiments, the display panel may further include an auxiliary electrode that covers the second electrode and may be directly in contact with the conductive barrier wall.

In one or more embodiments, the auxiliary electrode may cover a lower surface of the second barrier wall layer.

In one or more embodiments, the auxiliary electrode may be in contact with the first outer side surface of the first barrier wall layer.

In one or more embodiments, the auxiliary electrode may be electrically connected to the conductive barrier wall and the second electrode.

In one or more embodiments, the display panel may further include a lower encapsulation inorganic pattern that covers the auxiliary electrode, and the lower encapsulation inorganic pattern may be spaced and/or apart (e.g., spaced apart or separated) from the common electrode when viewed in a cross-section (e.g., in direction crossing the first or second direction or in a cross-sectional view of the display panel).

In one or more embodiments, the display panel may further include a pixel definition layer on the barrier insulating layer and defining a light emitting opening therethrough to expose at least a portion of the first electrode, and the light emitting opening may overlap the inner barrier wall opening.

One or more embodiments of the present disclosure provide a method of manufacturing a display panel. The method includes forming a circuit element layer including a transistor and a common electrode on a base layer, forming a preliminary conductive barrier wall on the common electrode, forming an inner barrier wall opening through the preliminary conductive barrier wall, forming a barrier insulating layer on the preliminary conductive barrier wall and in the inner barrier wall opening, forming a first electrode electrically connected to the transistor on the barrier insulating layer and in the inner barrier wall opening, forming a pixel definition layer covering the first electrode and on the barrier insulating layer, etching the preliminary conductive barrier wall to form a conductive barrier wall defining an outer barrier wall opening, forming a light emitting pattern covering the first electrode and a portion of the conductive barrier wall, and forming a second electrode electrically connected to the conductive barrier wall on the light emitting pattern.

In one or more embodiments, the forming of the inner barrier wall opening through the preliminary conductive barrier wall may include etching the preliminary conductive barrier wall to define the inner barrier wall opening to have a polygonal shape or a circular shape.

In one or more embodiments, the forming of the preliminary conductive barrier wall on the common electrode may include forming a first preliminary barrier wall layer on the common electrode and may include forming a second preliminary barrier wall layer on the first preliminary barrier wall layer. The forming of the inner barrier wall opening through the preliminary conductive barrier wall may include etching the preliminary conductive barrier wall so that a first inner side surface of the first preliminary barrier wall layer may be aligned with a second inner side surface of the second preliminary barrier wall layer.

In one or more embodiments, the etching of the preliminary conductive barrier wall to form the conductive barrier wall defining the outer barrier wall opening may include first etching the first preliminary barrier wall layer and the second preliminary barrier wall layer, and second etching the first preliminary barrier wall layer to form a first barrier wall layer and a second barrier wall layer.

In one or more embodiments, the method may further include forming an auxiliary electrode that covers the second electrode, may be directly in contact with the conductive barrier wall, and may electrically connect the conductive barrier wall and the second electrode.

In one or more embodiments, the method may further include forming a lower encapsulation inorganic pattern that covers the auxiliary electrode and may be spaced and/or apart (e.g., spaced apart or separated) from the common electrode when viewed in a cross-section.

One or more embodiments of the present disclosure provide an electronic apparatus including a circuit element layer including a transistor, a common electrode on the circuit element layer, a conductive barrier wall including a first barrier wall layer on the common electrode and a second barrier wall layer on the first barrier wall layer and defining an outer barrier wall opening and an inner barrier wall opening therethrough, a first electrode on the conductive barrier wall and in the inner barrier wall opening and electrically connected to the transistor through the inner barrier wall opening, a light emitting pattern on the first electrode and covering a portion of the second barrier wall layer, a second electrode covering the light emitting pattern, and an auxiliary electrode covering the second electrode and being in contact with a lower surface of the second barrier wall layer and a first outer side surface of the first barrier wall layer. The outer barrier wall opening is around (e.g., surrounds) the inner barrier wall opening when viewed in a plane (e.g., in a plan view of the display panel), and the auxiliary electrode is electrically connected to the conductive barrier wall and the second electrode.

According to the one or more embodiments, the inner barrier wall opening is formed to overlap the light emitting area, and the first electrode is electrically connected to the circuit element layer through the inner barrier opening of the conductive barrier wall. As the light emitting area and the inner barrier wall opening overlap each other, a size of an area from which light is emitted increases. In addition, because the light emitting element is formed in the inner barrier wall opening where the tip portion is not formed and on the conductive barrier wall, a shadow area is reduced or prevented from occurring in a deposition process. Accordingly, the display panel that (easily) enables high-resolution implementation is provided, and a thickness of the conductive barrier wall is reduced. The lower encapsulation inorganic pattern that covers the light emitting element formed on the conductive barrier wall has a more stable and sturdy structure without having a shape protruded from a center. In other words, the inner barrier wall opening may overlap the light-emitting area, allowing the first electrode to connect to the circuit element layer through this opening. This overlap increases the light-emitting area. Additionally, forming the light-emitting element within the inner barrier wall opening and on the conductive barrier wall reduces shadow areas during deposition. Consequently, the display panel supports high-resolution implementation and reduces the thickness of the conductive barrier wall. The lower encapsulation inorganic pattern covering the light-emitting element on the conductive barrier wall is more stable and sturdy without protruding from the center.

### BRIEF DESCRIPTION OF THE DRAWINGS

The above and other aspects, features and/or principles of embodiments of the present disclosure will become readily apparent by reference to the following detailed description when considered in conjunction with the accompanying drawings. In the drawings:

FIG. 1A is a perspective view of a display device according to one or more embodiments of the present disclosure;

FIG. 1B is an exploded perspective view of a display device according to one or more embodiments of the present disclosure;

FIG. 2 is a cross-sectional view of a display module according to one or more embodiments of the present disclosure;

FIG. 3 is a plan view of a display panel according to one or more embodiments of the present disclosure;

FIG. 4 is an enlarged plan view of a portion of a display area of a display panel according to one or more embodiments of the present disclosure;

FIG. 5 is a cross-sectional view taken along the line I-I′ of FIG. 4, according to one or more embodiments of the present disclosure;

FIG. 6 is a cross-sectional view of a portion of a display panel taken along the line II-II′ of FIG. 4, according to one or more embodiments of the present disclosure; and

FIGS. 7A to 7N are cross-sectional views illustrating processes of a method of manufacturing a display panel according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

Unless otherwise noted, like reference numerals denote like elements throughout the attached drawings and the written description, and thus, duplicative descriptions thereof may not be provided. In the drawings, the thickness, ratio, and dimension of components may be exaggerated for effective description and/or clarity. In the drawings, the relative sizes of elements, layers, and regions may be exaggerated for effective description and/or clarity.

As used herein, the term “and/or” may include any and all combinations of one or more of the associated listed items.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a”, “an” and “the” are intended to include the plural forms as well, unless the context clearly indicates otherwise.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof.

Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

Unless otherwise defined, all terms including technical and scientific terms used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, embodiments of the present disclosure will be described with reference to accompanying drawings.

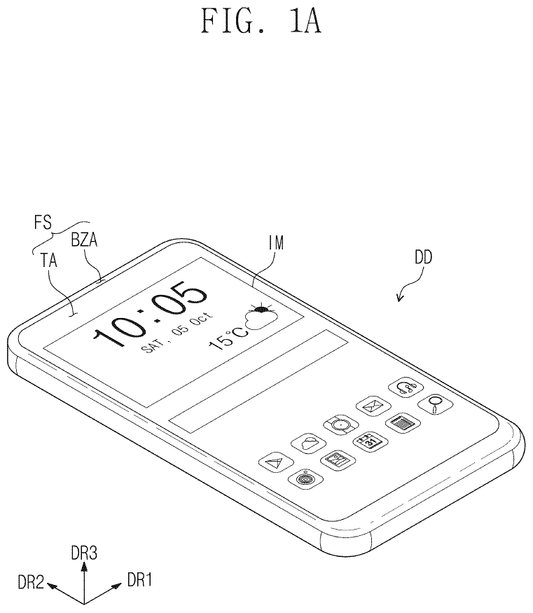

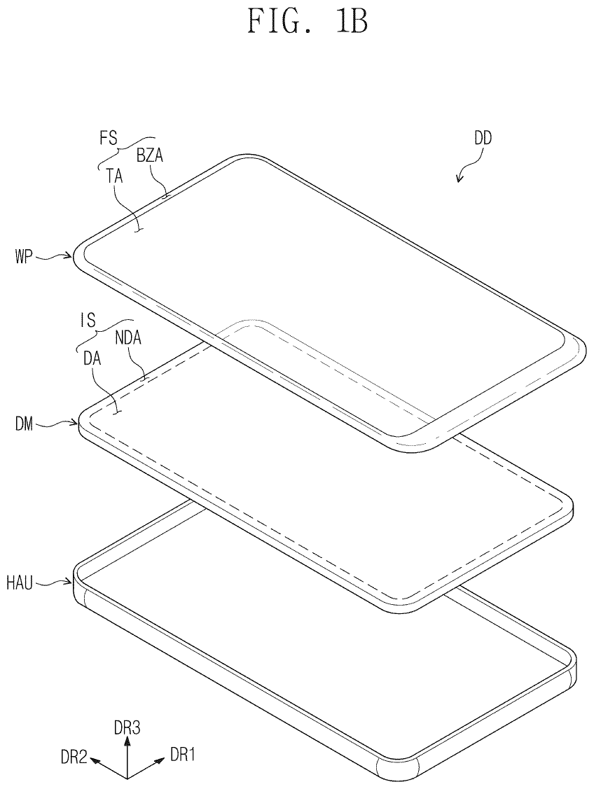

FIG. 1A is a perspective view of a display device DD according to one or more embodiments of the present disclosure. FIG. 1B is an exploded perspective view of the display device DD according to one or more embodiments of the present disclosure.

The display device DD may be applied to a large-sized electronic apparatus, such as a television set, a monitor, or an outdoor billboard. In addition, the display device DD may be applied to a small and medium-sized electronic apparatus, such as a personal computer, a notebook computer, a personal digital assistant, a car navigation unit, a game unit, a smartphone, a tablet computer, and/or a camera. However, these are merely examples, and the display device DD may be employed in other display devices as long as they do not deviate from the spirit and scope of the present disclosure. FIGS. 1A and 1B show the smartphone as a representative example of the display device DD.

Referring to FIGS. 1A and 1B, the display device DD may display an image IM through a display surface FS, which is substantially parallel to each of a first direction DR1 and a second direction DR2, and may display the image IM toward a third direction DR3. The image IM may include a still image as well as a video. FIG. 1A shows a clock widget and application icons as a representative example of the image IM. The display surface FS through which the image IM is displayed may correspond to a front surface of the display device DD.

In one or more embodiments, front (or upper) and rear (or lower) surfaces of each member of the display device DD may be defined with respect to a direction in which the image IM is displayed. The front and rear surfaces may be opposite to each other in the third direction DR3, and a normal (perpendicular) line direction of each of the front and rear surfaces may be substantially parallel to the third direction DR3. In one or more embodiments, directions indicated by the first, second, and third directions DR1, DR2, and DR3 may be relative to each other, and thus, the directions indicated by the first, second, and third directions DR1, DR2, and DR3 may be changed to other directions. In the following descriptions, the expression “when viewed in a plane” refers to a state of being viewed in the third direction DR3 from the top (e.g., the upper surface) of the device, i.e., a plan view.

The display device DD may include a window WP, a display module DM, and a housing HAU. The window WP and the housing HAU may be coupled to each other to provide an exterior of the display device DD.

The window WP may include an optically transparent insulating material. For example, the window WP may include a glass or plastic material. A front surface of the window WP may define the display surface FS of the display device DD. The display surface FS may include a transmissive area TA and a bezel area BZA. The transmissive area TA may be an optically transparent area. As an example, the transmissive area TA may be an area having a visible light transmittance of about 90% or more.

The bezel area BZA may be an area having a relatively lower transmittance than that of the transmissive area TA. The bezel area BZA may define a shape of the transmissive area TA. The bezel area BZA may be arranged adjacent to the transmissive area TA and may be around (e.g., may surround) the transmissive area TA. However, this is merely an example, and the bezel area BZA may not be provided in the window WP. The window WP may include at least one functional layer of an anti-fingerprint layer, a hard coating layer, and/or an anti-reflective layer. However, the present disclosure is not limited thereto.

The display module DM may be arranged under the window WP. The display module DM may have a configuration that (substantially) generates the image IM. The image IM generated by the display module DM may be displayed through a display surface IS of the display module DM and may be viewed by a user through the transmissive area TA.

The display module DM may include a display area DA and a non-display area NDA. The display area DA may be activated in response to electrical signals. The non-display area NDA may be adjacent to the display area DA. The non-display area NDA may be around (e.g., may surround) the display area DA. The non-display area NDA may be covered by the bezel area BZA and may not be viewed from the outside.

The housing HAU may be coupled with the window WP. The housing HAU and the window WP, which are coupled to each other, may provide a set or predetermined inner space. The display module DM may be accommodated in the inner space.

The housing HAU may include a material with a relatively high rigidity. As an example, the housing HAU may include a glass, plastic, or metal material or a plurality of frames and/or plates of combinations thereof. The housing HAU may stably protect the components of the display device DD accommodated in the inner space from external impacts.

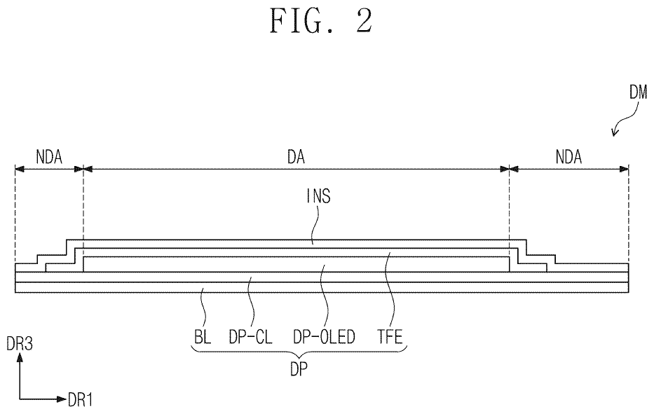

FIG. 2 is a cross-sectional view of the display module DM according to one or more embodiments of the present disclosure.

Referring to FIG. 2, the display module DM may include a display panel DP and an input sensor INS. In one or more embodiments, the display device DD (see, e.g., FIG. 1A) may further include a protective member arranged on a lower surface of the display panel DP or an anti-reflective member and/or a window member arranged on an upper surface of the input sensor INS.

The display panel DP may be a light emitting type or kind display panel; however, the present disclosure is not limited. thereto For example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot, a quantum rod, or a micro-LED. Hereinafter, the organic light emitting display panel will be described as the display panel DP.

The display panel DP may include a base layer BL, a circuit element layer DP-CL, a display element layer DP-OLED, and a thin film encapsulation layer TFE. The circuit element layer DP-CL, the display element layer DP-OLED, and the thin film encapsulation layer TFE may be arranged on the base layer BL. The input sensor INS may be arranged directly on the thin film encapsulation layer TFE. In the present disclosure, the expression “A component A is arranged directly on a component B.” means that no adhesive layers are present between the component A and the component B.

The base layer BL may include at least one plastic film. The base layer BL may be a flexible substrate and may include a plastic substrate, a glass substrate, a metal substrate, or an organic/inorganic composite material substrate. The display area DA and the non-display area NDA described with reference to FIG. 1B may also be defined in the base layer BL.

The circuit element layer DP-CL may include at least one insulating layer and a circuit element. The insulating layer may include at least one inorganic layer and at least one organic layer. The circuit element may include signal lines and a pixel driving circuit.

The display element layer DP-OLED may include a conductive barrier wall and a light emitting element. The light emitting element may include an anode, an intermediate layer, and a cathode.

The thin film encapsulation layer TFE may include a plurality of thin layers. Some thin layers may be arranged to improve optical efficiency, and some thin layers may be arranged to protect organic light emitting diodes.

The input sensor INS may obtain coordinate information of an external input. The input sensor INS may have a multi-layer structure. The input sensor INS may include a conductive layer having a single-layer or multi-layer structure. The input sensor INS may include an insulating layer having a single-layer or multi-layer structure. The input sensor INS may sense the external input by a capacitive method; however, the present disclosure should not be limited thereto or thereby. As an example, the input sensor INS may sense the external input by an electromagnetic induction method or a pressure sensing method. In one or more embodiments, the input sensor INS may not be provided.

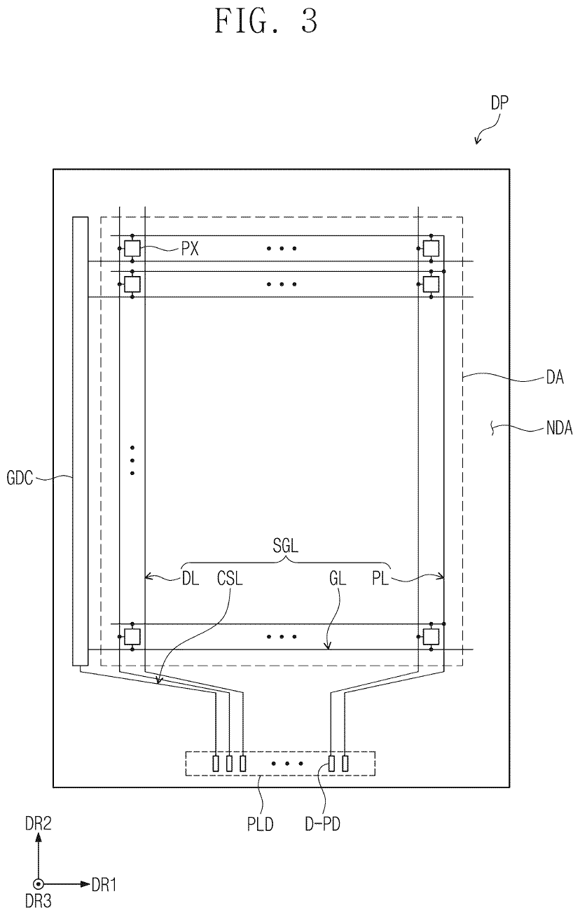

FIG. 3 is a plan view of the display panel DP according to one or more embodiments of the present disclosure.

Referring to FIG. 3, the display panel DP may include the display area DA and the non-display area NDA around the display area DA. The display panel DP may include pixels PX and signal lines SGL electrically connected to the pixels PX. The display panel DP may include a driving circuit GDC and a pad part PLD. The display area DA and the non-display area NDA may be distinguished from each other by a presence or absence of the pixels PX. The pixels PX may be arranged in the display area DA. The driving circuit GDC and the pad part PLD may be arranged in the non-display area NDA.

The pixels PX may be arranged in the first direction DR1 and the second direction DR2. The pixels PX may include a plurality of pixel rows extending in the first direction DR1 and arranged in the second direction DR2 and a plurality of pixel columns extending in the second direction DR2 and arranged in the first direction DR1.

The signal lines SGL may include gate lines GL, data lines DL, a power line PL, and a control signal line CSL. Each of the gate lines GL may be connected to a corresponding pixel among the pixels PX, and each of the data lines DL may be connected to a corresponding pixel among the pixels PX. The power line PL may be electrically connected to the pixels PX. The control signal line CSL may be connected to the driving circuit GDC and may provide control signals to the driving circuit GDC.

The driving circuit GDC may include a gate driving circuit. The gate driving circuit may generate a plurality of gate signals and may sequentially output the gate signals to the gate lines GL. The gate driving circuit may further output other control signals to the pixel driving circuit.

The pad part PLD may be connected to a flexible circuit board. The pad part PLD may include pixel pads D-PD, and the pixel pads D-PD may be pads to connect the flexible circuit board to the display panel DP. Each of the pixel pads D-PD may be connected to a corresponding signal line among the signal lines SGL. The pixel pads D-PD may be connected to corresponding pixels PX via the signal lines SGL. In addition, the driving circuit GDC may be connected to one pixel pad among the pixel pads D-PD.

In addition, the pad part PLD may further include input pads. The input pads may be pads to connect the flexible circuit board to the input sensor INS (see, e.g., FIG. 2); however, the present disclosure should not be limited thereto or thereby. According to one or more embodiments, the input pads may be arranged in the input sensor INS (see, e.g., FIG. 2) and may be connected to a different circuit board from a circuit board to which the pixel pads D-PD are connected. According to one or more embodiments, the input sensor INS (see, e.g., FIG. 2) may not be provided, and the pad part PLD may not further include the input pads.

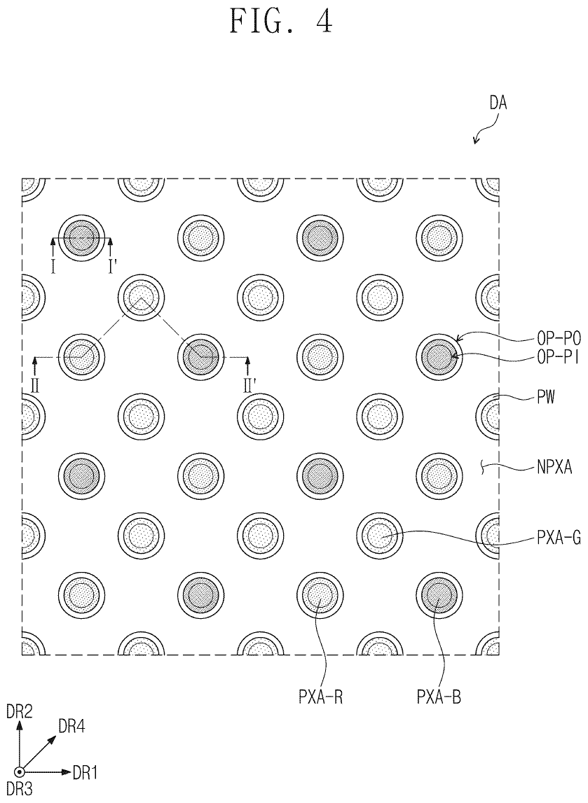

FIG. 4 is an enlarged plan view of a portion of the display area DA (see, e.g., FIG. 2) of the display panel DP (see, e.g., FIG. 2) according to one or more embodiments of the present disclosure. FIG. 4 is a plan view showing the display module DM when viewed from an upper side of the display surface IS (see, e.g., FIG. 1B) of the display module DM (see, e.g., FIG. 1B) and shows an arrangement of light emitting areas PXA-R, PXA-G, and PXA-B and the conductive barrier wall PW.

Referring to FIG. 4, the display area DA may include first, second, and third light emitting areas PXA-R, PXA-G, and PXA-B and a peripheral area NPXA around (e.g., surrounding) the first, second, and third light emitting areas PXA-R, PXA-G, and PXA-B. The first, second, and third light emitting areas PXA-R, PXA-G, and PXA-B may respectively correspond to areas from which lights provided from light emitting elements are emitted. The first, second, and third light emitting areas PXA-R, PXA-G, and PXA-B may be distinguished from each other by colors of the lights emitted outward from the display module DM (see, e.g., FIG. 2).

The first, second, and third light emitting areas PXA-R, PXA-G, and PXA-B may respectively provide first, second, and third color lights having colors different from each other. As an example, the first color light may be a red light, the second color light may be a green light, and the third color light may be a blue light. However, the first, second, and third color lights should not be limited thereto or thereby.

Each of the first, second, and third light emitting areas PXA-R, PXA-G, and PXA-B may be defined as an area through which an upper surface of the anode is exposed by a light emitting opening described in more detail later. The peripheral area NPXA may define a boundary between the first, second, and third light emitting areas PXA-R, PXA-G, and PXA-B and may prevent or reduce a mixture of the colors of the lights between the first, second, and third light emitting areas PXA-R, PXA-G, and PXA-B. In other words, the peripheral area NPXA may prevent or reduce the likelihood of the light (e.g., the different color lights) from the first, second, and third light emitting areas PXA-R, PXA-G, and PXA-B from mixing in the area between the first, second, and third light emitting areas PXA-R, PXA-G, and PXA-B.

Each of the first, second, and third light emitting areas PXA-R, PXA-G, and PXA-B may be provided in plural and may be repeatedly arranged in a set or predetermined arrangement within the display area DA. As an example, the first and third light emitting areas PXA-R and PXA-B may be alternately arranged with each other in the first direction DR1 to form a first group. The second light emitting areas PXA-G may be arranged in the first direction DR1 to form a second group. Each of the first group and the second group may be provided in plural, and the first groups may be alternately arranged with the second groups in the second direction DR2.

One second light emitting area PXA-G may be arranged spaced and/or apart (e.g., spaced apart or separated) from one first light emitting area PXA-R or one third light emitting area PXA-B in a fourth direction DR4. The fourth direction DR4 may correspond to a direction between the first and second directions DR1 and DR2.

For example, FIG. 4 shows a representative example of the arrangement of the first, second, and third light emitting areas PXA-R, PXA-G, and PXA-B, and the arrangement of the first, second, and third light emitting areas PXA-R, PXA-G, and PXA-B may be changed in one or more suitable ways and should not be particularly limited. The first, second, and third light emitting areas PXA-R, PXA-G, and PXA-B may be arranged in a Pentile pattern (PENTILE® is a duly registered trademark of Samsung Display Co., Ltd.) as shown in FIG. 4. According to one or more embodiments, the first, second, and third light emitting areas PXA-R, PXA-G, and PXA-B may be arranged in a stripe pattern or a diamond pattern (Diamond Pixel® is a duly registered trademark of Samsung Display Co., Ltd.).

Each of the first, second, and third light emitting areas PXA-R, PXA-G, and PXA-B may have a variety of shapes when viewed in a plane. As an example, each of the first, second, and third light emitting areas PXA-R, PXA-G, and PXA-B may have a polygonal shape, a circular shape, or an oval shape. In FIG. 4, the first, second, and third light emitting areas PXA-R, PXA-G, and PXA-B each having the circular shape are shown as a representative example.

The first, second, and third light emitting areas PXA-R, PXA-G, and PXA-B may have substantially the same shape as each other when viewed in the plane (e.g., in the plan view), or at least one of the first, second, and third light emitting areas PXA-R, PXA-G, and PXA-B may have a shape different from the others. FIG. 4 shows a structure in which the first, second, and third light emitting areas PXA-R, PXA-G, and PXA-B have the same shape as each other when viewed in the plane; however, the present disclosure should not be limited thereto or thereby. As an example, the first and third light emitting areas PXA-R and PXA-B may have the same shape as each other when viewed in the plane, and the second light emitting area PXA-G may have the shape different from those of the first and third light emitting areas PXA-R and PXA-B, as a representative example.

FIG. 4 shows a structure in which the first, second, and third light emitting areas PXA-R, PXA-G, and PXA-B have substantially the same size as each other when viewed in the plane; however, the present disclosure should not be limited thereto or thereby. As an example, at least one of the first, second, and third light emitting areas PXA-R, PXA-G, and PXA-B may have a size different from those of the others when viewed in the plane. According to one or more embodiments, the size of the first light emitting area PXA-R emitting the red light may be greater than the size of the second light emitting area PXA-G emitting the green light and may be smaller than the size of the third light emitting area PXA-B emitting the blue light.

In one or more embodiments, the shape, size, and arrangement of the first, second, and third light emitting areas PXA-R, PXA-G, and PXA-B of the display module DM (see, e.g., FIG. 2) may be designed in one or more suitable ways depending on the colors of the emitted lights, the size of the display module DM (see, e.g., FIG. 2), and the configuration of the display module DM (see, e.g., FIG. 2), and they should not be limited to one or more embodiments shown in FIG. 4.

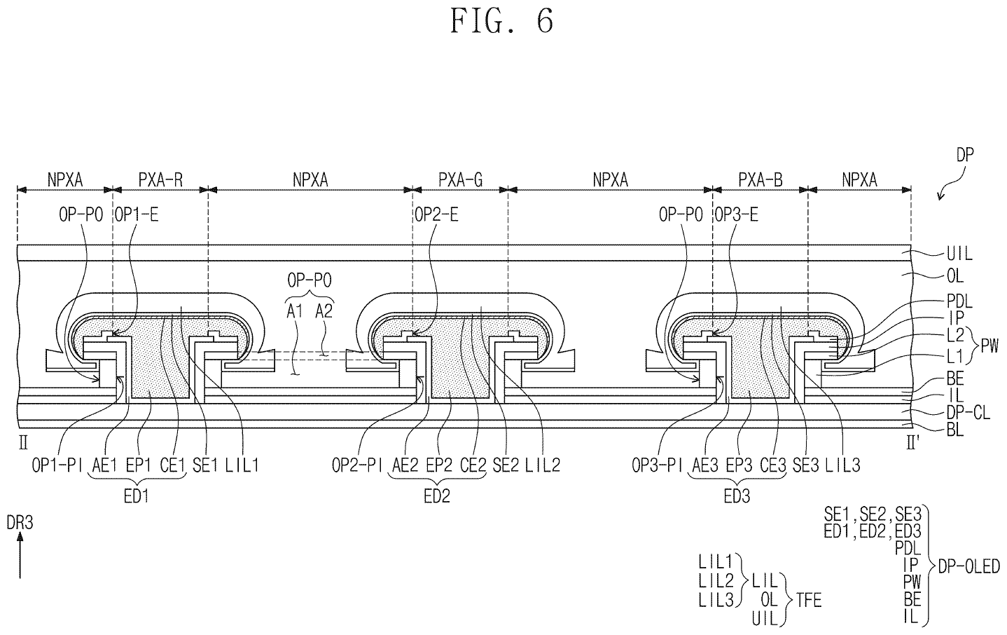

The conductive barrier wall PW may be provided with an inner barrier wall opening OP-PI and an outer barrier wall opening OP-PO, which are defined therethrough. The inner barrier wall opening OP-PI may overlap a center of each of the first, second, and third light emitting areas PXA-R, PXA-G, and PXA-B when viewed in the plane. For example, the inner barrier wall opening OP-PI may overlap a center of each of first, second, and third light emitting patterns EP1, EP2, and EP3 (see, e.g., FIG. 6) when viewed in the plane as described in more detail later. In other words, the conductive barrier wall PW may be provided with an inner barrier wall opening OP-PI and an outer barrier wall opening OP-PO, which are defined therethrough. The inner barrier wall opening OP-PI may overlap the center of each of the first, second, and third light-emitting areas PXA-R, PXA-G, and PXA-B in a plan view. For example, the inner barrier wall opening OP-PI may overlap the center of each of the first, second, and third light-emitting patterns EP1, EP2, and EP3 (see, e.g., FIG. 6) in the plan view.

The inner barrier wall opening OP-PI and the outer barrier wall opening OP-PO may have a variety of shapes when viewed in the plane. As an example, each of the inner barrier wall opening OP-PI and the outer barrier wall opening OP-PO may have a polygonal shape, a circular shape, or an oval shape. In FIG. 4, the inner barrier wall opening OP-PI and the outer barrier wall opening OP-PO each having the circular shape when viewed in the plane are shown as a representative example.

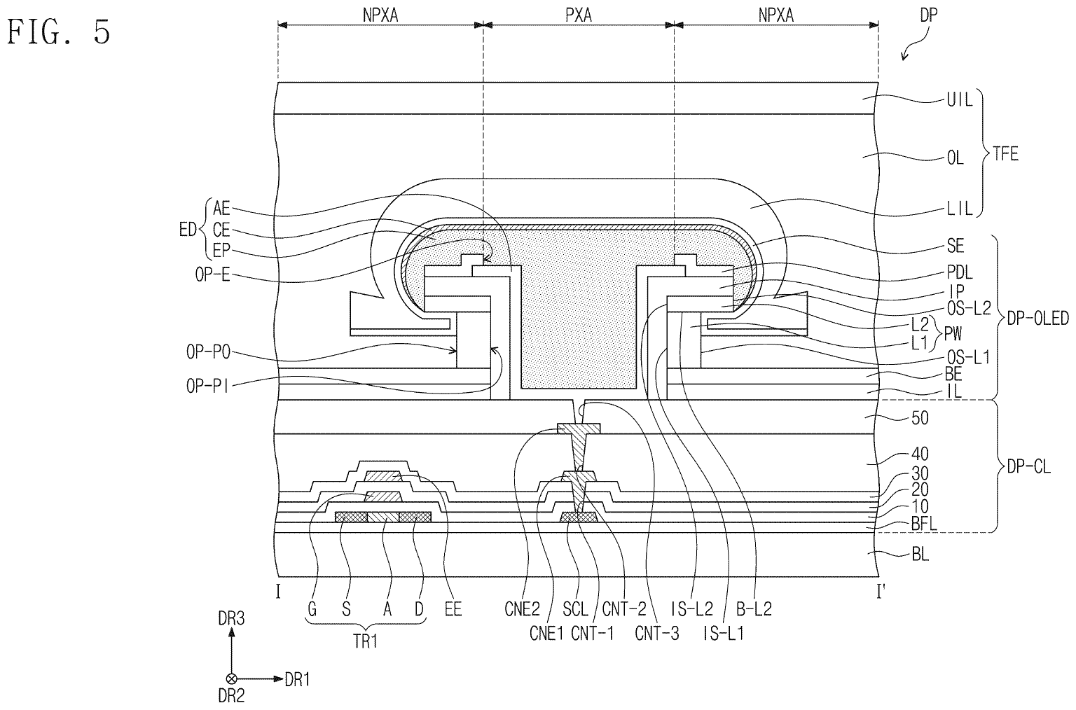

The inner barrier wall opening OP-PI of the conductive barrier wall PW may overlap a first electrode AE (see, e.g., FIG. 5) described in more detail later, and the outer barrier wall opening OP-PO of the conductive barrier wall PW may be spaced and/or apart (e.g., spaced apart or separated) from the first electrode AE when viewed in the plane, as described in more detail later. The outer barrier wall opening OP-PO may be around (e.g., surround) the inner barrier wall opening OP-PI when viewed in the plane.

FIG. 5 is a cross-sectional view taken along the line I-I′ of FIG. 4. In FIG. 5, the same reference numerals denote the same elements in FIG. 2, and thus, detailed descriptions of the same elements may not be provided.

FIG. 5 is an enlarged view of one light emitting area PXA in the display area DA (see, e.g., FIG. 4), and the light emitting area PXA of FIG. 5 corresponds to one of the first, second, and third light emitting areas PXA-R, PXA-G, and PXA-B (see, e.g., FIG. 4).

Referring to FIG. 5, the display panel DP may include the base layer BL, the circuit element layer DP-CL, the display element layer DP-OLED, and the thin film encapsulation layer TFE.

The display panel DP may include a plurality of insulating layers, a semiconductor pattern, a conductive pattern, and a signal line. An insulating layer, a semiconductor layer, and a conductive layer may be formed by a coating or depositing process. Then, the insulating layer, the semiconductor layer, and the conductive layer may be selectively patterned by a photolithography process and an etching process. The semiconductor pattern, the conductive pattern, and the signal line, which are included in the circuit element layer DP-CL and the display element layer DP-OLED, may be formed through the above processes.

The circuit element layer DP-CL may be arranged on the base layer BL. The circuit element layer DP-CL may include a buffer layer BFL, a transistor TR1, a signal transmission area SCL, first, second, third, fourth, and fifth insulating layers 10, 20, 30, 40, and 50, an electrode EE, and a plurality of connection electrodes CNE1 and CNE2.

The buffer layer BFL may be arranged on the base layer BL. The buffer layer BFL may increase an adhesive force between the base layer BL and the semiconductor pattern. The buffer layer BFL may include a silicon oxide layer and a silicon nitride layer, and the silicon oxide layer and the silicon nitride layer may be alternately stacked with each other.

The semiconductor pattern may be arranged on the buffer layer BFL. The semiconductor pattern may include polysilicon; however, the present disclosure should not be limited thereto or thereby. The semiconductor pattern may include an amorphous silicon or metal oxide. FIG. 5 shows a portion of the semiconductor pattern, and the semiconductor pattern may be further arranged in the light emitting areas PXA-R, PXA-G, and PXA-B (see, e.g., FIG. 4). The semiconductor pattern may be arranged with a specific rule over the light emitting areas PXA-R, PXA-G, and PXA-B. The semiconductor pattern may have different electrical properties depending on whether it is doped or not. The semiconductor pattern may include a first region having a relatively high doping concentration and a second region having a relatively low doping concentration. The first region may be doped with an N-type (kind) dopant or a P-type (kind) dopant. A P-type (kind) transistor may include the first region doped with the P-type (kind) dopant.

The first region may have a conductivity greater than that of the second region and may substantially serve as an electrode or a signal line. The second region may substantially correspond to an active (e.g., active region or channel) of the transistor. For example, a portion of the semiconductor pattern may be the active of the transistor, another portion of the semiconductor pattern may be a source or a drain of the transistor, and the other portion of the semiconductor pattern may be a conductive area.

A source S, an active (e.g., active region) A, and a drain D of the transistor TR1 may be formed from the semiconductor pattern. FIG. 5 shows a portion of the signal transmission area SCL formed from the semiconductor pattern. In one or more embodiments, the signal transmission area SCL may be connected to the drain D of the transistor TR1 in a plane (e.g., along the same plane). For example, the signal transmission area SCL may be connected to the drain D of transistor TR1 in the same plane.

The first, second, third, fourth, and fifth insulating layers 10, 20, 30, 40, and 50 may be arranged on the buffer layer BFL. Each of the first to fifth insulating layers 10 to 50 may be an inorganic layer or an organic layer.

The first insulating layer 10 may be arranged on the buffer layer BFL. The first insulating layer 10 may cover the source S, the active A, and the drain D of the transistor TR1 and the signal transmission area SCL. A gate G (e.g., a gate electrode G) of the transistor TR1 may be arranged on the first insulating layer 10. The second insulating layer 20 may be arranged on the first insulating layer 10 and may cover the gate G. The electrode EE may be arranged on the second insulating layer 20. The third insulating layer 30 may be arranged on the second insulating layer 20 and may cover the electrode EE.

A first connection electrode CNE1 may be arranged on the third insulating layer 30. The first connection electrode CNE1 may be connected to the signal transmission area SCL via a contact hole CNT-1 defined through the first, second, and third insulating layers 10, 20, and 30. The fourth insulating layer 40 may be arranged on the third insulating layer 30 and may cover the first connection electrode CNE1. The fourth insulating layer 40 may be an organic layer.

A second connection electrode CNE2 may be arranged on the fourth insulating layer 40. The second connection electrode CNE2 may be connected to the first connection electrode CNE1 via a contact hole CNT-2 defined through the fourth insulating layer 40. The fifth insulating layer 50 may be arranged on the fourth insulating layer 40 and may cover the second connection electrode CNE2. The fifth insulating layer 50 may be an organic layer. The fifth insulating layer 50 may be provided with a contact hole CNT-3 defined therethrough. The first electrode AE described in more detail later may be connected to the second connection electrode CNE2 through the contact hole CNT-3.

The display element layer DP-OLED may be arranged on the circuit element layer DP-CL. The display element layer DP-OLED may include an insulating layer IL, a common electrode BE, the conductive barrier wall PW, a barrier insulating layer IP, a light emitting element ED, and an auxiliary electrode SE.

The insulating layer IL may be arranged on the circuit element layer DP-CL. For example, the insulating layer IL may be arranged on the fifth insulating layer 50 and may cover the fifth insulating layer 50.

The common electrode BE may be arranged on the insulating layer IL. As an example, the common electrode BE may be arranged on the circuit element layer DP-CL. The common electrode BE may be entirely arranged over (e.g., arranged over the entirety of) the display area DA (see, e.g., FIG. 4) and may apply a common voltage. As an example, the common electrode BE may be arranged to overlap all of the first, second, and third light emitting areas PXA-R, PXA-G, and PXA-B (see, e.g., FIG. 6).

The conductive barrier wall PW may be arranged on the common electrode BE. The conductive barrier wall PW may be provided with the inner barrier wall opening OP-PI and the outer barrier wall opening OP-PO. The inner barrier wall opening OP-PI may be an opening to connect the anode AE to the second connection electrode CNE2, and the outer barrier wall opening OP-PO may be an opening to pattern a light emitting pattern EP and the cathode CE without using a fine metal mask (FMM).

The inner barrier wall opening OP-PI may overlap a center of each of the anode AE and the light emitting pattern EP, and the outer barrier wall opening OP-PO may not overlap the center of each of the anode AE and the light emitting pattern EP. For example, the inner barrier wall opening OP-PI may overlap the light emitting opening OP-E described in more detail later, and the outer barrier wall opening OP-PO may not overlap the light emitting opening OP-E.

The outer barrier wall opening OP-PO of the conductive barrier wall PW may have an undercut shape when viewed in a cross-section (e.g., when viewed in direction crossing the first direction DR1 or the second direction DR2 or in a cross-sectional view). The conductive barrier wall PW may include a plurality of layers sequentially stacked, and at least one layer of the layers may be recessed with respect to the other layers. Accordingly, the conductive barrier wall PW may have a tip portion. FIG. 5 shows one undercut shape as a representative example, however, the shape of the outer barrier wall opening OP-PO should not be limited thereto or thereby. As an example, the outer barrier wall opening OP-PO may have two or more undercut shapes.

The conductive barrier wall PW may include a first barrier wall layer L1 and a second barrier wall layer L2. The first barrier wall layer L1 may be arranged on the common electrode BE, and the second barrier wall layer L2 may be arranged on the first barrier wall layer L1. As shown in FIG. 5, the first barrier wall layer L1 may have a thickness greater than a thickness of the second barrier wall layer L2, but the present disclosure should not be limited thereto or thereby. According to one or more embodiments, FIG. 5 shows the structure in which each of the common electrode BE, the first barrier wall layer L1, and the second barrier wall layer L2 is provided as a single layer as a representative example; however, the present disclosure should not be limited thereto or thereby. As an example, each of the common electrode BE, the first barrier wall layer L1, and the second barrier wall layer L2 may include two or more layers.

A first inner side surface IS-L1 of the first barrier wall layer L1 and a second inner side surface IS-L2 of the second barrier wall layer L2, which define the inner barrier wall opening OP-PI, may be aligned with each other. For example, the inner barrier wall opening OP-PI may not have a protruding shape and may be defined by the inner side surfaces IS-L1 and IS-L2 formed continuously (e.g., formed to provide a continuous surface in which the first inner side surface IS-L1 and the second inner side surface IS-L2 are flush and even with each other).

The first barrier wall layer L1 may be recessed more than the second barrier wall layer L2 with respect to the peripheral area NPXA. The first barrier wall layer L1 may be undercut with respect to the second barrier wall layer L2. A portion of the second barrier wall layer L2, which is protruded in a direction from the first barrier wall layer L1 toward the center of the outer barrier wall opening OP-PO, may be defined as a tip portion in the conductive barrier wall PW.

The outer barrier wall opening OP-PO may include a first area A1 (see, e.g., FIG. 6) defined by a first outer side surface OS-L1 of the first barrier wall layer L1 and a second area A2 (see, e.g., FIG. 6) defined by a second outer side surface OS-L2 of the second barrier wall layer L2. The first area A1 and the second area A2 may be provided integrally with each other. The first area A1 may have a width different from a width of the second area A2. As an example, a length in one direction of the first area A1 may be greater than a length in the one direction (e.g., the same direction) of the second area A2. The one direction may be normal (e.g., perpendicular) to a thickness direction, e.g., the third direction DR3, of the circuit element layer DP-CL. The one direction may be the first direction DR1 or the second direction DR2. For example, the second area A2 of the outer barrier wall opening OP-PO may be an area that defines the tip portion. The second area A2 may have a width smaller than a width of the first area A1 due to the tip portion.

Each of the first barrier wall layer L1, the second barrier wall layer L2, and the common electrode BE may include a conductive material. As an example, the conductive material may include a metal, a transparent conductive oxide (TCO), an organic material, an inorganic material, and/or one or more (e.g., any suitable) combinations thereof. As an example, the metal may include gold (Au), silver (Ag), aluminum (Al), magnesium (Mg), lithium (Li), molybdenum (Mo), titanium (Ti), copper (Cu), and/or alloys thereof. The transparent conductive oxide may include indium tin oxide (ITO), indium zinc oxide (IZO), zinc oxide, indium oxide, indium gallium oxide, indium gallium zinc oxide (IGZO), and/or aluminum zinc oxide. The inorganic material may include silicon nitride (SiNₓ, where x is 0<x≤2, e.g., Si₃N₄, etc.) or silicon oxynitride (SiON). The barrier wall layer including the inorganic material may have a refractive index within a range from about 1.3 to about 2.3.

The second barrier wall layer L2 may include the same material as the common electrode BE, and the first barrier wall layer L1 and the second barrier wall layer L2 may include different materials from each other; however, this is merely an example and the present disclosure is not limited thereto or thereby.

FIG. 5 shows the structure in which each of the inner side surfaces IS-L1 and IS-L2 or each of outer side surfaces OS-L1 and OS-L2 of the conductive barrier wall PW are normal (e.g., perpendicular) to an upper surface of the common electrode BE as a representative example; however, the present disclosure should not be limited thereto or thereby. As an example, the conductive barrier wall PW may have a tapered shape or a reverse-tapered shape.

The barrier insulating layer IP may be arranged on the conductive barrier wall PW. The barrier insulating layer IP arranged on the conductive barrier wall PW may prevent or reduce the likelihood of the conductive barrier wall PW from being electrically connected to the anode AE (or the first electrode). The barrier insulating layer IP may cover side surfaces of the conductive barrier wall PW, the common electrode BE, and the insulating layer IL, which define the inner barrier wall opening OP-PI.

The light emitting element ED may include the anode AE (or the first electrode), the light emitting pattern EP, and the cathode CE (or a second electrode).

The anode AE may be arranged on the barrier insulating layer IP and in the inner barrier wall opening OP-PI. The anode AE may be arranged between the common electrode BE and the cathode CE when viewed in the cross-section. The anode AE may be arranged on the barrier insulating layer IP and may be connected to the second connection electrode CNE2 through the contact hole CNT-3 that is not covered by the barrier insulating layer IP. Accordingly, the anode AE may be electrically connected to the signal transmission area SCL through the first and second connection electrodes CNE1 and CNE2 and thus may be electrically connected to a corresponding circuit element, e.g., the transistor TR1.

The anode AE may be a transmissive electrode, a semi-transmissive electrode, or a reflective electrode. The anode AE may have a single-layer or multi-layer structure. The anode AE may include a plurality of layers including indium tin oxide (ITO) or silver (Ag). As an example, the anode AE may include a layer (hereinafter, referred to as a lower ITO layer) containing indium tin oxide (ITO), a layer (hereinafter, referred to as an Ag layer) arranged on the lower ITO layer and containing silver (Ag), and a layer (hereinafter, referred to as an upper ITO layer) arranged on the Ag layer and containing indium tin oxide (ITO).

The light emitting pattern EP may be arranged on the anode AE. The light emitting pattern EP may include a light emitting layer containing a light emitting material. The light emitting pattern EP may further include a hole injection layer (HIL) and a hole transport layer (HTL), which are arranged between the anode AE and the light emitting layer, and may further include an electron transport layer (ETL) and an electron injection layer (EIL), which are arranged on the light emitting layer. The light emitting pattern EP may be referred to as an organic layer or an intermediate layer.

The light emitting pattern EP may be patterned by the tip portion defined in the conductive barrier wall PW. The light emitting pattern EP may be formed on the anode AE to cover a portion of the conductive barrier wall PW and the barrier insulating layer IP. As an example, the light emitting pattern EP may be patterned by the tip portion defined in the conductive barrier wall PW and may cover the side surface of the barrier insulating layer IP and at least a portion of the second outer side surface OS-L2 of the second barrier wall layer L2.

The cathode CE may be patterned by the tip portion defined in the conductive barrier wall PW. The cathode CE may cover at least a portion of the light emitting pattern EP. The cathode CE may be electrically connected to the conductive barrier wall PW through the auxiliary electrode SE.

The cathode CE may include a conductive material (e.g., a conductor). The cathode CE may be formed of one or more suitable materials having conductivity, such as a metal, a transparent conductive oxide (TCO), or a conductive polymer material. As an example, the cathode CE may include silver (Ag), magnesium (Mg), lead (Pb), copper (Cu), and/or compounds thereof. The cathode CE may be electrically connected to the conductive barrier wall PW. Details of the cathode CE will be described in more detail later.

The auxiliary electrode SE may be arranged on the cathode CE (or the second electrode). The auxiliary electrode SE may cover the cathode CE and may be directly in contact with the conductive barrier wall PW. The auxiliary electrode SE may be in contact with a lower surface B-L2 of the second barrier wall layer L2 and the first outer side surface OS-L1 of the first barrier wall layer L1. As an example, the auxiliary electrode SE may cover the cathode CE and may extend along the lower surface B-L2 of the second barrier wall layer L2 and the first outer side surface OS-L1 of the first barrier wall layer L1; however, the shape of the auxiliary electrode SE should not be limited thereto or thereby. According to one or more embodiments, the auxiliary electrode SE may include a portion that covers the cathode CE and the lower surface B-L2 of the second barrier wall layer L2 and a portion that is in contact with the first outer side surface OS-L1 of the first barrier wall layer L1 without extending from the lower surface B-L2 of the second barrier wall layer L2.

The auxiliary electrode SE may include a conductive material. As an example, the conductive material may include a metal, a transparent conductive oxide (TCO), and/or one or more (e.g., any suitable) combinations thereof. As an example, the metal may include gold (Au), silver (Ag), aluminum (Al), magnesium (Mg), lithium (Li), molybdenum (Mo), titanium (Ti), copper (Cu), and/or alloys thereof. The transparent conductive oxide may include indium tin oxide (ITO), indium zinc oxide (IZO), zinc oxide, indium oxide, indium gallium oxide, indium gallium zinc oxide (IGZO), and/or aluminum zinc oxide.

The auxiliary electrode SE may be in contact with the cathode CE and the conductive barrier wall PW to electrically connect the cathode CE and the conductive barrier wall PW. The conductive barrier wall PW may receive a driving voltage (or a bias voltage), and thus, the cathode CE may receive the driving voltage (or the bias voltage).

The display element layer DP-OLED may further include a pixel definition layer PDL. The pixel definition layer PDL may be arranged on the barrier insulating layer IP. The pixel definition layer PDL may be provided with the light emitting opening OP-E defined therethrough to expose at least a portion of the anode AE. The light emitting opening OP-E may overlap (or correspond to) the anode AE, and at least the portion of the anode AE may be exposed through the light emitting opening OP-E of the pixel definition layer PDL. The light emitting opening OP-E may overlap the inner barrier wall opening OP-PI of the conductive barrier wall PW. The pixel definition layer PDL may include an inorganic insulating material. As an example, the pixel definition layer PDL may include silicon nitride (SiNₓ, where 0<x≤2).

The thin film encapsulation layer TFE may be arranged on the display element layer DP-OLED. The thin film encapsulation layer TFE may include a lower encapsulation inorganic pattern LIL, an encapsulation organic layer OL, and an upper encapsulation inorganic layer UIL.

The lower encapsulation inorganic pattern LIL may be formed to correspond to (or overlap) the light emitting opening OP-E or the inner barrier wall opening OP-PI. For example, the lower encapsulation inorganic pattern LIL may be formed to overlap the light emitting element ED. The lower encapsulation inorganic pattern LIL may be arranged on the auxiliary electrode SE and may cover the auxiliary electrode SE. The lower encapsulation inorganic pattern LIL may be spaced and/or apart (e.g., spaced apart or separated) from the common electrode BE when viewed in the cross-section.

The encapsulation organic layer OL may be arranged on the lower encapsulation inorganic pattern LIL, may cover the lower encapsulation inorganic pattern LIL, and may provide a flat upper surface thereon. A portion of the encapsulation organic layer OL may be filled in an area (hereinafter, referred to as a dummy area) in which the lower encapsulation inorganic pattern LIL is spaced and/or apart (e.g., spaced apart or separated) from the common electrode BE when viewed in the cross-section. However, the shape of the encapsulation organic layer OL is merely an example, and the present disclosure should not be limited thereto or thereby. As an example, the encapsulation organic layer OL may not be filled in the dummy area, and the dummy area may remain empty.

The upper encapsulation inorganic layer UIL may be arranged on the encapsulation organic layer OL. The upper encapsulation inorganic layer UIL may include an inorganic material.

The lower encapsulation inorganic pattern LIL and the upper encapsulation inorganic layer UIL may protect the display element layer DP-OLED from moisture and oxygen, and the encapsulation organic layer OL may protect the display element layer DP-OLED from a foreign substance such as dust particles.

According to embodiments of the present disclosure, the inner barrier wall opening OP-PI may be formed to overlap the light emitting area PXA, and the first electrode AE may be electrically connected to the circuit element layer DP-CL via the inner barrier wall opening OP-PI of the conductive barrier wall PW. As the light emitting area PXA overlaps the inner barrier wall opening OP-PI, the light emitting area may increase. In addition, because the light emitting element ED is formed in the inner barrier wall opening OP-PI where the tip portion is not formed and above the conductive barrier wall PW, a shadow area may be reduced or prevented from occurring in a deposition process. Accordingly, the display panel DP that easily enables high-resolution implementation may be provided, and the thickness of the conductive barrier wall PW may be reduced. The lower encapsulation inorganic pattern LIL that covers the light emitting element ED formed on the conductive barrier wall PW may have a more stable and sturdy structure without having a shape protruded from the center.

FIG. 6 is a cross-sectional view of a portion of the display panel DP taken along a line II-II′ of FIG. 4, according to one or more embodiments of the present disclosure. FIG. 6 is an enlarged cross-sectional view of one first light emitting area PXA-R, one second light emitting area PXA-G, and one third light emitting area PXA-B, and descriptions of the light emitting area PXA of FIG. 5 may be applied to the first, second, and third light emitting areas PXA-R, PXA-G, and PXA-B of FIG. 6.

Referring to FIGS. 5 and 6, the display panel DP may include the base layer BL, the circuit element layer DP-CL, the display element layer DP-OLED, and the thin film encapsulation layer TFE. The display element layer DP-OLED may include the insulating layer IL, the common electrode BE, the conductive barrier wall PW, the barrier insulating layer IP, the pixel definition layer PDL, light emitting elements ED1, ED2, and ED3, and auxiliary electrodes SE1, SE2, and SE3.

The light emitting elements ED1, ED2, and ED3 may include a first light emitting element ED1, a second light emitting element ED2, and a third light emitting element ED3. The first light emitting element ED1 may include a first anode AE1, the first light emitting pattern EP1, and a first cathode CE1. The second light emitting element ED2 may include a second anode AE2, the second light emitting pattern EP2, and a second cathode CE2. The third light emitting element ED3 may include a third anode AE3, the third light emitting pattern EP3, and a third cathode CE3. The first, second, and third anodes AE1, AE2, and AE3 may be provided in the form of patterns. The first light emitting pattern EP1 may provide the red light, the second light emitting pattern EP2 may provide the green light, and the third light emitting pattern EP3 may provide the blue light.

The display element layer DP-OLED may further include the pixel definition layer PDL. The pixel definition layer PDL may be arranged on the barrier insulating layer IP. The pixel definition layer PDL may be provided with first, second, and third light emitting openings OP1-E, OP2-E, and OP3-E defined therethrough. At least a portion of the first anode AE1 may be exposed through the first light emitting opening OP1-E. At least a portion of the second anode AE2 may be exposed through the second light emitting opening OP2-E. At least a portion of the third anode AE3 may be exposed through the third light emitting opening OP3-E.

In the present disclosure, the first light emitting area PXA-R may be defined as an area of an upper surface of the first anode AE1, which is exposed through the first light emitting opening OP1-E. The second light emitting area PXA-G may be defined as an area of an upper surface of the second anode AE2, which is exposed through the second light emitting opening OP2-E. The third light emitting area PXA-B may be defined as an area of an upper surface of the third anode AE3, which is exposed through the third light emitting opening OP3-E.

First, second, and third inner barrier wall openings OP1-PI, OP2-PI, and OP3-PI that correspond to the first, second, and third light emitting openings OP1-E, OP2-E, and OP3-E, respectively, may be defined through the conductive barrier wall PW, and the outer barrier wall openings OP-PO that do not overlap the first, second, and third light emitting openings OP1-E, OP2-E, and OP3-E may be defined through (by) the conductive barrier wall PW.

The first, second, and third inner barrier wall openings OP1-PI, OP2-PI, and OP3-PI may overlap the center of the first, second, and third light emitting patterns EP1, EP2, and EP3. As an example, the first inner barrier wall opening OP1-PI may overlap the center of the first light emitting pattern EP1, the second inner barrier wall opening OP2-PI may overlap the center of the second light emitting pattern EP2, and the third inner barrier wall opening OP3-PI may overlap the center of the third light emitting pattern EP3.

The first inner side surface IS-L1 of the first barrier wall layer L1 and the second inner side surface IS-L2 of the second barrier wall layer L2, which defined the first, second, and third inner barrier wall openings OP1-PI, OP2-PI, and OP3-PI, may be aligned with each other. For example, the inner barrier wall opening OP-PI may not have a protruding shape and may be defined by the inner side surfaces IS-L1 and IS-L2 formed continuously (e.g., formed to provide a continuous surface in which the first inner side surface IS-L1 and the second inner side surface IS-L2 are flush and even with each other).

The outer barrier wall openings OP-PO may overlap the peripheral area NPXA around (e.g., surrounding) the first, second, and third light emitting areas PXA-R, PXA-G, and PXA-B. The outer barrier wall openings OP-PO may have the undercut shape when viewed in the cross-section.

The outer barrier wall openings OP-PO may include the first area A1 defined by the first outer side surface OS-L1 of the first barrier wall layer L1 and the second area A2 defined by the second outer side surface OS-L2 of the second barrier wall layer L2. The first area A1 and the second area A2 may be provided integrally with each other as an opening. The length in the one direction of the first area A1 may be greater than the length in the one direction (e.g., the same direction) of the second area A2. The one direction may be the first direction DR1 or the second direction DR2. For example, the second area A2 of the outer barrier wall openings OP-PO may be an area that defines the tip portion. The second area A2 may have the width smaller than the width of the first area A1 due to the tip portion.

The first, second, and third light emitting patterns EP1, EP2, and EP3 may be physically separated from each other by the second barrier wall layer L2 forming the tip portion and may be formed to cover the second outer side surfaces OS-L2 of the second barrier wall layer L2. In addition, the first, second, and third cathodes CE1, CE2, and CE3 may be physically separated from each other by the second barrier wall layer L2 forming the tip portion, and each of the first, second, and third cathodes CE1, CE2, and CE3 may be formed to cover at least a portion of a corresponding light emitting pattern EP1, EP2, or EP3.

According to one or more embodiments of the present disclosure, the first light emitting patterns EP1 may be patterned in the unit of pixel by the tip portion defined in the conductive barrier wall PW and may be deposited. For example, the first light emitting patterns EP1 may be commonly formed using an open mask but may be easily separated in the unit of pixel by the conductive barrier wall PW.

In contrast, in a case where the first light emitting patterns EP1 are patterned using a fine metal mask (FMM), a support spacer protruded from the conductive barrier wall may be used to support the fine metal mask. In addition, because the fine metal mask is spaced and/or apart (e.g., spaced apart or separated) from a base surface on which a patterning process is performed by a height of the barrier wall and the spacer, there may be limitations in implementing high resolution. Further, because the fine metal mask is in contact with the spacer, a foreign substance may remain on the spacer after the patterning process of the first light emitting patterns EP1, or the spacer may be damaged by the fine metal mask. As a result, a defective display panel may be formed.

According to one or more embodiments, as the display panel DP includes the conductive barrier wall PW, the light emitting elements ED1, ED2, and ED3 may be easily physically separated from each other. Accordingly, a leakage current or a driving error between the light emitting areas PXA-R, PXA-G, and PXA-B adjacent to each other may be prevented or reduced, and the light emitting elements ED1, ED2, and ED3 may be driven independently from each other.

For example, because the first light emitting patterns EP1 are patterned without a mask that is in contact with components provided inside the display area DA (see, e.g. FIG. 1B), the defect rate of the display panel DP may be reduced, and thus, the electronic apparatus with improved process reliability may be provided. Even though the support spacer protruded from the conductive barrier wall PW is not provided, the first light emitting patterns EP1 may be patterned. Therefore, the light emitting areas PXA-R, PXA-G, and PXA-B may be finely formed in terms of its size, and thus, the display panel DP that easily enables high-resolution implementation may be provided.

In addition, because a large-sized mask may not be used if (e.g., when) manufacturing a large-sized display panel, the process cost may be reduced, and because the display panel is not affected by the defects occurring due to the large-sized mask, the process reliability of the display panel may be improved. Descriptions of the first light emitting patterns EP1 may be applied to the second and third light emitting patterns EP2 and EP3.

The auxiliary electrodes SE1, SE2, and SE3 may include a first auxiliary electrode SE1, a second auxiliary electrode SE2, and a third auxiliary electrode SE3. The first auxiliary electrode SE1 may cover the first cathode CE1, the second auxiliary electrode SE2 may cover the second cathode CE2, and the third auxiliary electrode SE3 may cover the third cathode CE3. The first, second, and third auxiliary electrodes SE1, SE2, and SE3 may be directly in contact with the lower surface B-L2 of the second barrier wall layer L2 and may cover the lower surface B-L2 of the second barrier wall layer L2.

The first auxiliary electrode SE1 may be in contact with the first cathode CE1 and the conductive barrier wall PW to electrically connect the first cathode CE1 and the conductive barrier wall PW. The conductive barrier wall PW may receive the driving voltage (or the bias voltage), and thus, the first cathode CE1 may receive the driving voltage (or the bias voltage). The second auxiliary electrode SE2 may be in contact with the second cathode CE2 and the conductive barrier wall PW to electrically connect the second cathode CE2 and the conductive barrier wall PW. The conductive barrier wall PW may receive the driving voltage (or the bias voltage), and thus, the second cathode CE2 may receive the driving voltage (or the bias voltage). The third auxiliary electrode SE3 may be in contact with the third cathode CE3 and the conductive barrier wall PW to electrically connect the third cathode CE3 and the conductive barrier wall PW. The conductive barrier wall PW may receive the driving voltage (or the bias voltage), and thus, the third cathode CE3 may receive the driving voltage (or the bias voltage).

The thin film encapsulation layer TFE may include the lower encapsulation inorganic patterns LIL, the encapsulation organic layer OL, and the upper encapsulation inorganic layer UIL.

The lower encapsulation inorganic patterns LIL may include a first lower encapsulation inorganic pattern LIL1, a second lower encapsulation inorganic pattern LIL2, and a third lower encapsulation inorganic pattern LIL3. The first, second, and third lower encapsulation inorganic patterns LIL1, LIL2, and LIL3 may be spaced and/or apart (e.g., spaced apart or separated) from the common electrode BE when viewed in the cross-section.

The first lower encapsulation inorganic pattern LIL1 may be formed to correspond to (or overlap in a plan view) the first light emitting opening OP1-E. The first lower encapsulation inorganic pattern LIL1 may be arranged on the first auxiliary electrode SE1 and may cover the first auxiliary electrode SE1. The second lower encapsulation inorganic pattern LIL2 may be formed to correspond to (or overlap in the plan view) the second light emitting opening OP2-E. The second lower encapsulation inorganic pattern LIL2 may be arranged on the second auxiliary electrode SE2 and may cover the second auxiliary electrode SE2. The third lower encapsulation inorganic pattern LIL3 may be formed to correspond to (or overlap in the plan view) the third light emitting opening OP3-E. The third lower encapsulation inorganic pattern LIL3 may be arranged on the third auxiliary electrode SE3 and may cover the third auxiliary electrode SE3.

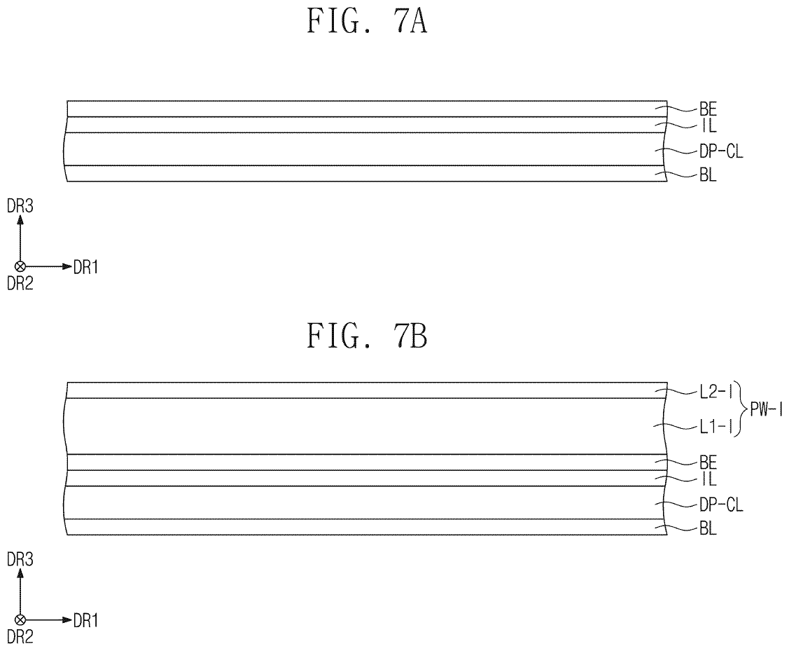

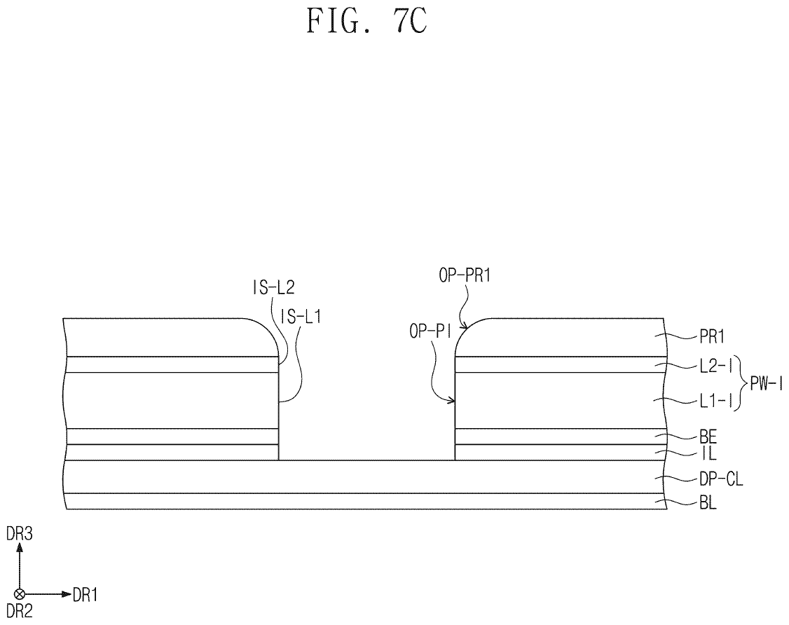

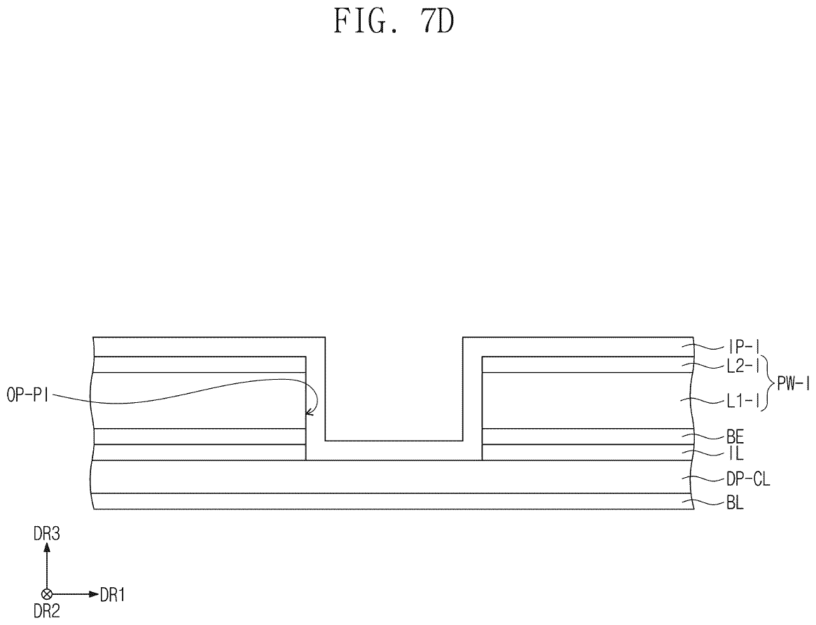

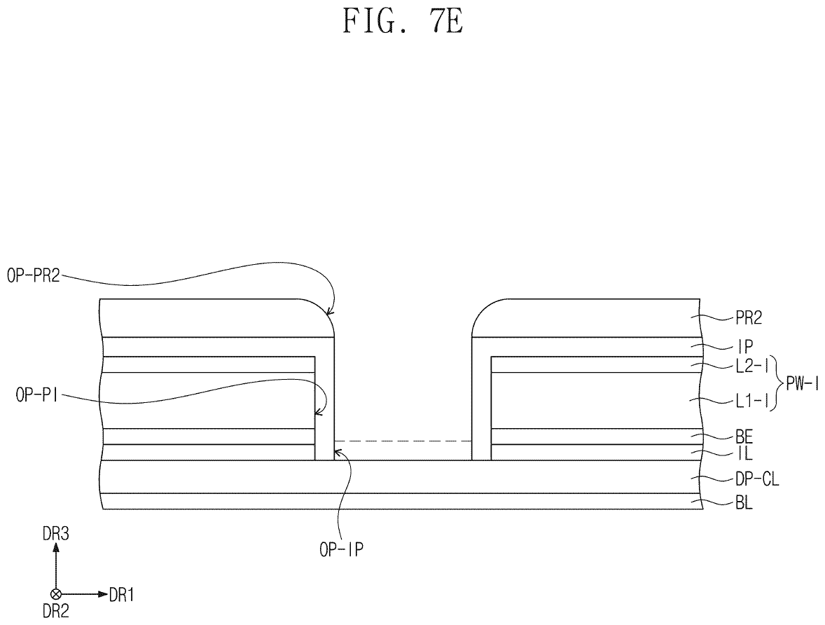

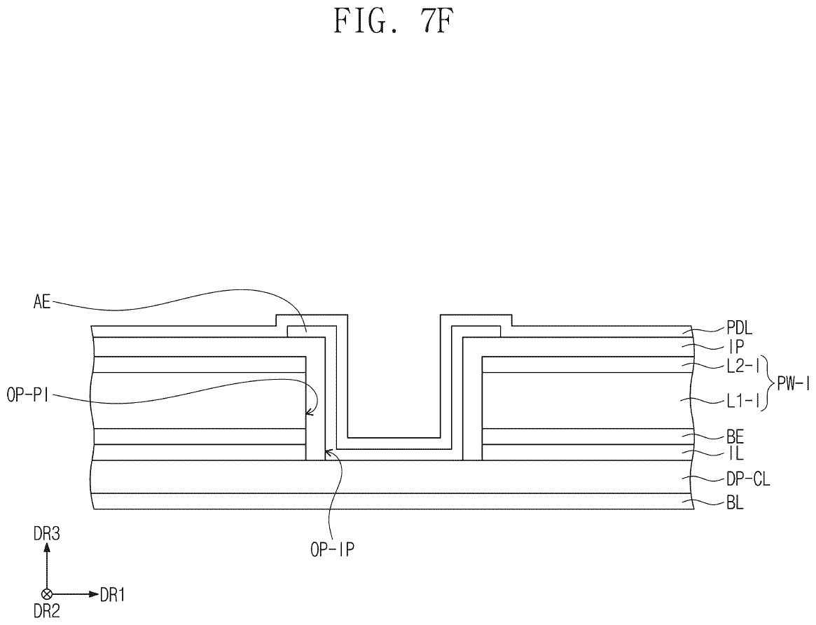

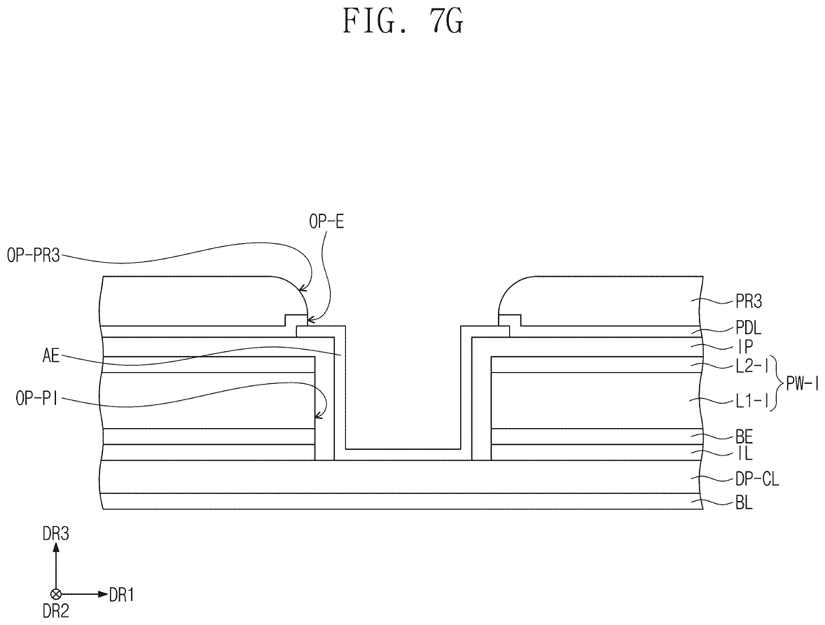

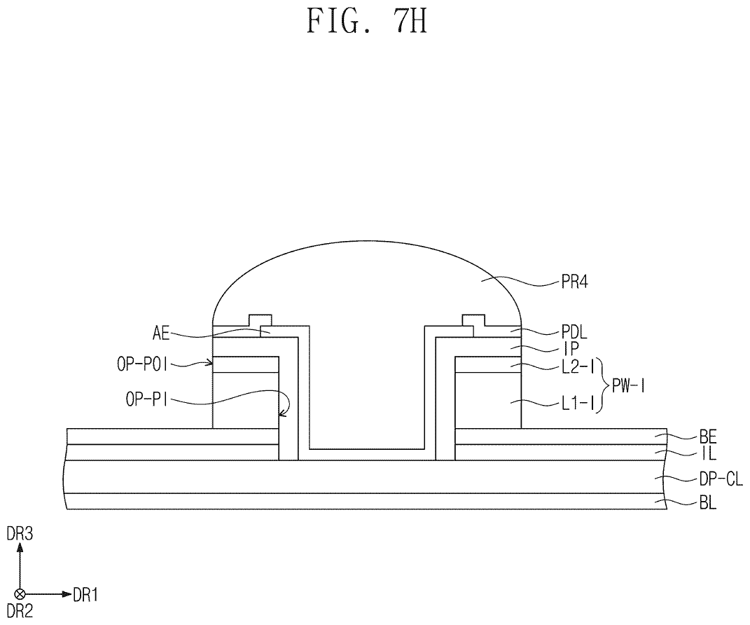

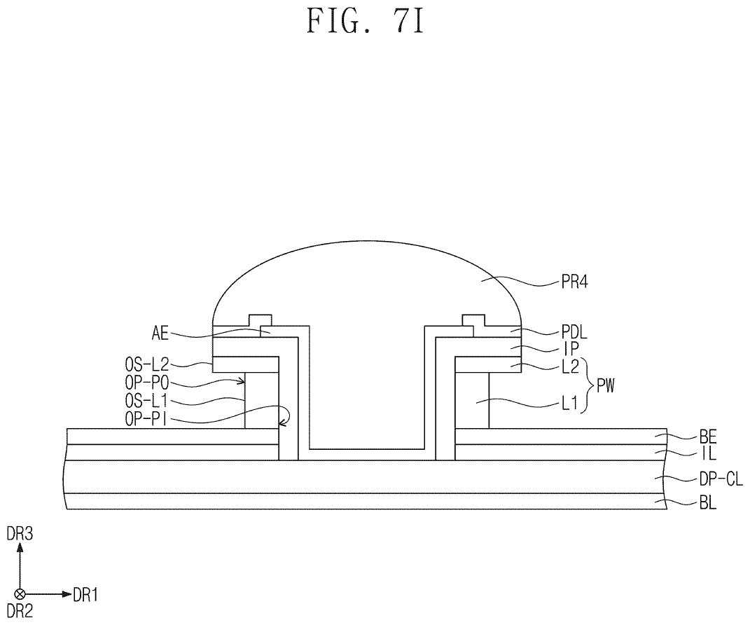

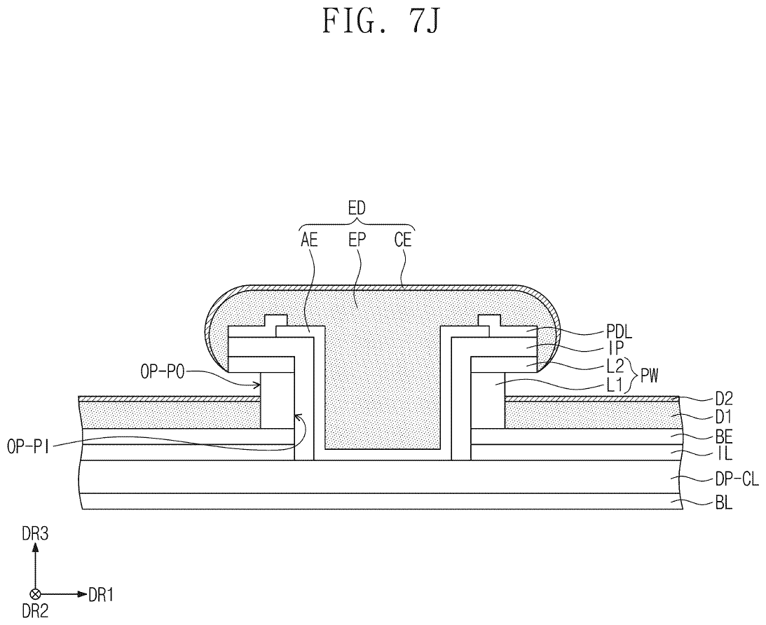

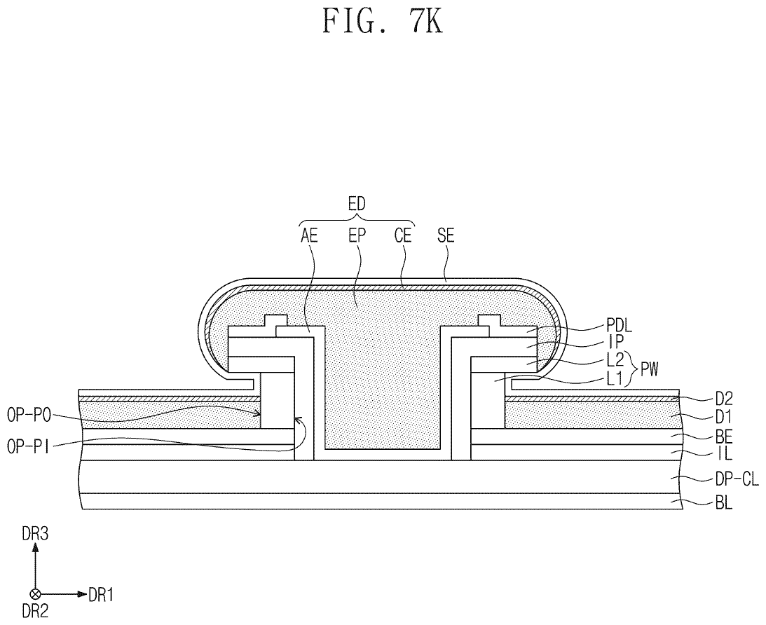

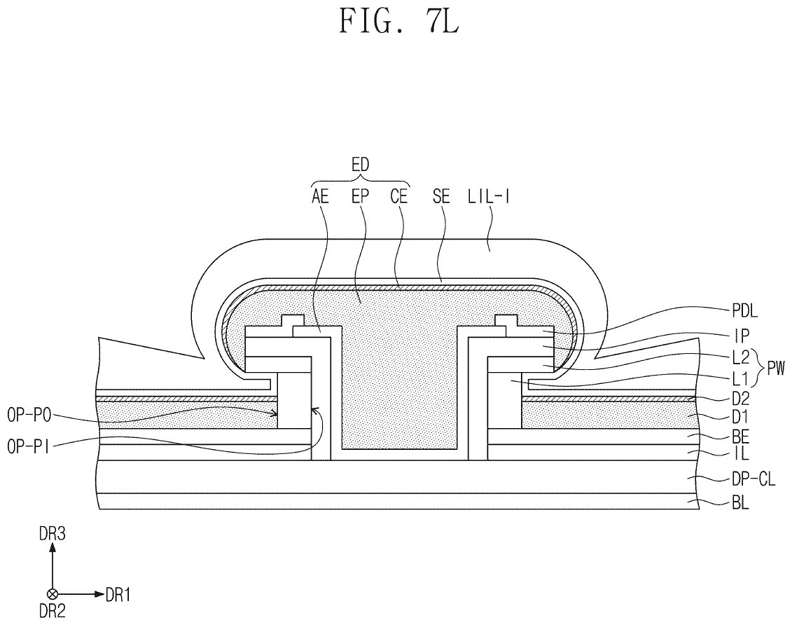

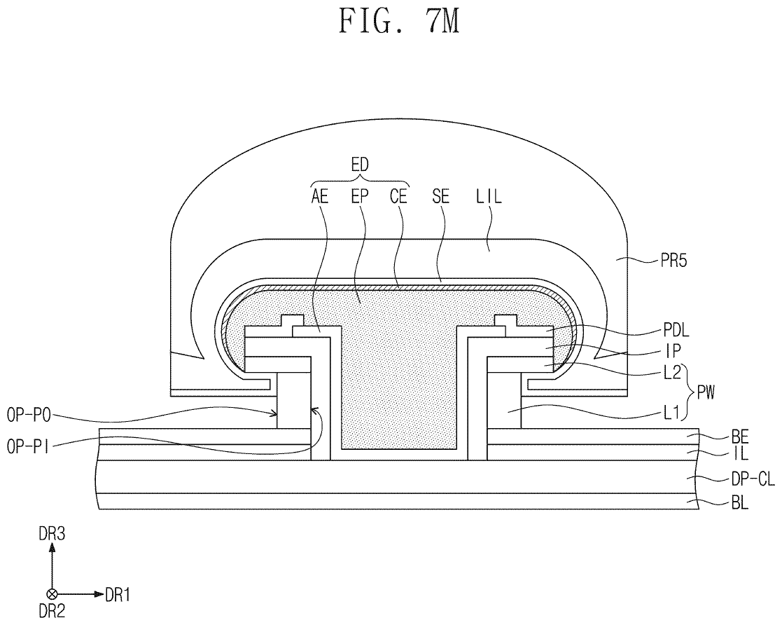

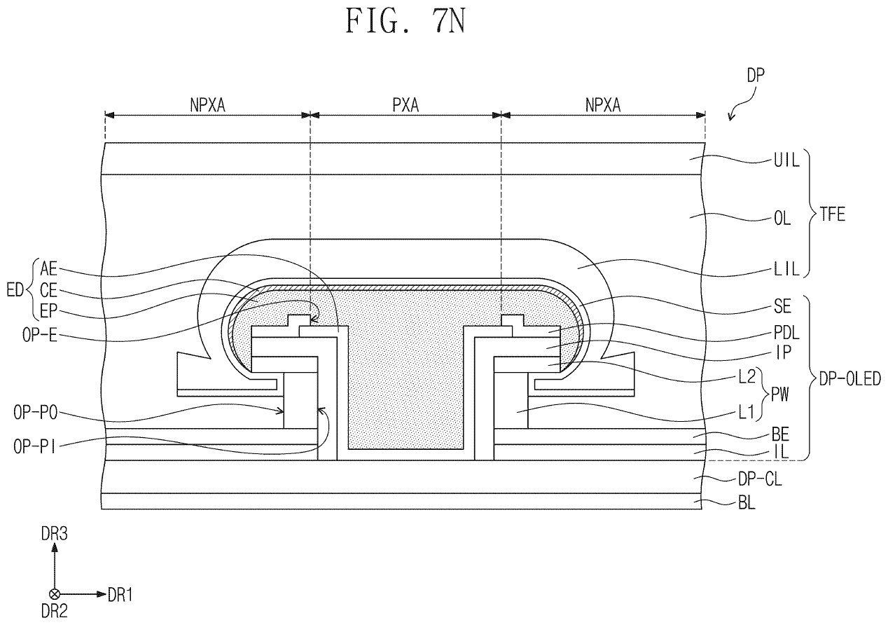

FIGS. 7A to 7N are cross-sectional views illustrating processes of a method of manufacturing the display panel according to one or more embodiments of the present disclosure. In FIGS. 7A to 7N, the same/similar reference numerals denote the same/similar elements in FIGS. 1 to 6, and thus, detailed descriptions of the same/similar elements may not be provided.

The manufacturing method of the display panel may include forming the circuit element layer including the transistor and the common electrode on the base layer, forming a preliminary conductive barrier wall on the common electrode, forming the inner barrier wall opening through the preliminary conductive barrier wall, forming the barrier insulating layer on the preliminary conductive barrier wall and in the inner barrier wall opening, forming the first electrode electrically connected to the transistor in the inner barrier wall opening and the pixel definition layer covering the first electrode on the barrier insulating layer, etching the preliminary conductive barrier wall to form the conductive barrier wall through which the outer barrier wall opening is defined, forming the light emitting pattern covering the first electrode and a portion of the conductive barrier wall, and forming the second electrode electrically connected to the conductive barrier wall on the light emitting pattern.

Hereinafter, a method of forming one light emitting element, e.g., the first light emitting element ED1 (see, e.g., FIG. 6), the lower encapsulation inorganic pattern, e.g., the first lower encapsulation inorganic pattern LIL1 (see, e.g., FIG. 6), covering the first light emitting element ED1, the encapsulation organic layer OL, and the upper encapsulation inorganic layer UIL will be described with reference to FIGS. 7A to 7N. The display panel formed through the processes of FIGS. 7A to 7N may correspond to the display panel DP of FIG. 5.

Referring to FIG. 7A, the manufacturing method of the display panel may include the forming of the circuit element layer DP-CL including the transistor TR1 (see, e.g., FIG. 6) and the common electrode BE on the base layer BL.

The circuit element layer DP-CL including the transistor TR1 may be formed through a generally available and/or generally utilized manufacturing process of the circuit element, which forms the insulating layer, the semiconductor layer, and the conductive layer by a coating or depositing process and selectively patterns the insulating layer, the semiconductor layer, and the conductive layer using photolithography and etching processes to form the semiconductor pattern, the conductive pattern, and the signal line. The manufacturing method of the display panel may further include depositing the insulating layer IL on the circuit element layer DP-CL.

The common electrode BE may be formed on the base layer BL. For example, the common electrode BE may be formed on the insulating layer IL. The common electrode BE may be commonly arranged over the display area DA (see, e.g., FIG. 4) and may be formed to provide the common voltage.

Referring to FIG. 7B, the manufacturing method of the display panel may include the forming of the preliminary conductive barrier wall PW-I on the common electrode BE. The forming of the preliminary conductive barrier wall PW-I may include forming a first preliminary barrier wall layer L1-I on the common electrode BE and forming a second preliminary barrier wall layer L2-I on the first preliminary barrier wall layer L1-I.

The forming of the first and second preliminary barrier wall layers L1-I and L2-I may be performed by a process of depositing a conductive material. As an example, the conductive material may include a metal, a transparent conductive oxide (TCO), an organic material, an inorganic material, and/or one or more (e.g., any suitable) combinations thereof. As an example, the metal may include gold (Au), silver (Ag), aluminum (Al), magnesium (Mg), lithium (Li), molybdenum (Mo), titanium (Ti), copper (Cu), and/or alloys thereof. The transparent conductive oxide may include indium tin oxide (ITO), indium zinc oxide (IZO), zinc oxide, indium oxide, indium gallium oxide, indium gallium zinc oxide (IGZO), or aluminum zinc oxide. The inorganic material may include silicon nitride (SiNₓ, where 0<x≤2) or silicon oxynitride (SiON). The preliminary barrier wall layer including the inorganic material may have a refractive index within a range from about 1.3 to about 2.3.

The second preliminary barrier wall layer L2-I may include the same material as the common electrode BE, and the first preliminary barrier wall layer L1-I and the second preliminary barrier wall layer L2-I may include different materials from each other; however, this is merely an example and the present disclosure is not limited thereto.

Referring to FIG. 7C, the manufacturing method of the display panel may further include forming a first photoresist layer PR1 on the preliminary conductive barrier wall PW-I. The first photoresist layer PR1 may be formed by forming a preliminary photoresist layer on the preliminary conductive barrier wall PW-I and patterning the preliminary photoresist layer using a photomask. A first photo opening OP-PR1 may be formed through the first photoresist layer PR1 by the patterning process. The first photo opening OP-PR1 may have a polygonal shape or a circular shape when viewed in the plane.

Then, the manufacturing method of the display panel may include the forming the inner barrier wall opening OP-PI through the preliminary conductive barrier wall PW-I after removing the first photoresist layer PR1. The forming of the inner barrier wall opening OP-PI may include etching the preliminary conductive barrier wall PW-I using the first photoresist layer PR1 as a mask. As an example, the preliminary conductive barrier wall PW-I may be dry-etched to allow the inner barrier wall opening OP-PI to have the polygonal shape or the circular shape.

In addition, the forming of the inner barrier wall opening OP-PI may include etching the preliminary conductive barrier wall PW-I so that the first inner side surface IS-L1 of the first preliminary barrier wall layer L1-I may be aligned with (e.g., even or flush with) the second inner side surface IS-L2 of the second preliminary barrier wall layer L2-1. The dry etch process to form the inner barrier wall opening OP-PI may be performed under an environment in which the first preliminary barrier wall layer L1-I has substantially the same etch selectivity with respect to the second preliminary barrier wall layer L2-1. Accordingly, the first inner side surface IS-L1 of the first preliminary barrier wall layer L1-I may be substantially aligned with the second inner side surface IS-L2 of the second preliminary barrier wall layer L2-I.

Referring to FIGS. 7D and 7E, the manufacturing method of the display panel may include the forming of the barrier insulating layer IP on the preliminary conductive barrier wall PW-I and in the inner barrier wall opening OP-PI.

Referring to FIG. 7D, the forming of the barrier insulating layer IP may include forming a preliminary barrier insulating layer IP-I on the preliminary conductive barrier wall PW-I. The preliminary barrier insulating layer IP-I may be formed on the preliminary conductive barrier wall PW-I. For example the preliminary barrier insulating layer IP-I may be formed to cover an upper surface of the second preliminary barrier wall layer L2-1, a side surface of the second preliminary barrier wall layer L2-I, a side surface of the first preliminary barrier wall layer L1-I, a side surface of the common electrode BE, a side surface of the insulating layer IL, and an upper surface of the circuit element layer DP-CL. For example, the preliminary barrier insulating layer IP-I may be formed to cover the inner barrier wall opening OP-PI.

Then, referring to FIG. 7E, the manufacturing method of the display panel may further include forming a second photoresist layer PR2 on the preliminary barrier insulating layer IP-I (see, e.g., FIG. 7D). The second photoresist layer PR2 may be formed by forming a preliminary photoresist layer on the preliminary barrier insulating layer IP-I and patterning the preliminary photoresist layer using a photomask. A second photo opening OP-PR2 may be formed through the second photoresist layer PR2 by the patterning process. The second photo opening OP-PR2 may overlap the inner barrier wall opening OP-PI.

The manufacturing method of the display panel may include etching the preliminary barrier insulating layer IP-I to form a barrier insulating layer opening OP-IP. A portion of the preliminary barrier insulating layer IP-I, which covers the upper surface of the circuit element layer DP-CL, may be removed by the etching process. The barrier insulating layer opening OP-IP may be formed in an area corresponding to the removed portion, and the barrier insulating layer IP may be formed from the preliminary barrier insulating layer IP-I. A portion of the upper surface of the circuit element layer DP-CL may be exposed through the barrier insulating layer opening OP-IP.

Referring to FIG. 7F, the manufacturing method of the display panel may include forming the first electrode AE (or the anode) and the pixel definition layer PDL that covers the first electrode AE after removing the second photoresist layer PR2.

The first electrode AE may be formed on the barrier insulating layer IP and in the inner barrier wall opening OP-PI (or the barrier insulating layer opening OP-IP). The first electrode AE may be electrically connected to the circuit element layer DP-CL via the inner barrier wall opening OP-PI. For example, the first electrode AE may be in contact with the upper surface, which is not covered by the barrier insulating layer IP, of the circuit element layer DP-CL and may be connected to the second connection electrode CNE2 (see, e.g., FIG. 5) via the contact hole CNT-3 (see, e.g., FIG. 5). Accordingly, the first electrode AE may be electrically connected to the signal transmission area SCL through the first and second connection electrodes CNE1 and CNE2 and may be electrically connected to the corresponding circuit element, e.g., the transistor TR1 (see, e.g., FIG. 5).

The pixel definition layer PDL may be formed on the barrier insulating layer IP and the first electrode AE to cover the first electrode AE.

Referring to FIG. 7G, the manufacturing method of the display panel may include forming a third photoresist layer PR3 on the pixel definition layer PDL. The third photoresist layer PR3 may be formed by forming a preliminary photoresist layer on the pixel definition layer PDL and patterning the preliminary photoresist layer using a photomask. A third photo opening OP-PR3 may be formed through the third photoresist layer PR3 to overlap the anode AE by the patterning process.

The manufacturing method of the display panel may include etching the pixel definition layer PDL to form the light emitting opening OP-E to overlap the anode AE (or the first electrode).

The etching of the pixel definition layer PDL may be performed by dry-etching a portion of the pixel definition layer PDL using the third photoresist layer PR3 as a mask. The light emitting opening OP-E may be formed by removing the etched portion of the pixel definition layer PDL, and the light emitting opening OP-E may overlap the anode AE (or the first electrode).

Referring to FIGS. 7H and 7I, the manufacturing method of the display panel may include the etching of the preliminary conductive barrier wall PW-I (see, e.g., FIG. 7G) to form the conductive barrier wall PW through which the outer barrier wall opening OP-PO is formed after removing the third photoresist layer PR3.

Referring to FIG. 7H, the forming of the conductive barrier wall PW may include first etching the first preliminary barrier wall layer L1-I and the second preliminary barrier wall layer L2-1. The first etching may be performed by dry-etching the first and second preliminary barrier wall layers L1-I and L2-I using a fourth photoresist layer PR4 as a mask. The etched portion of the preliminary conductive barrier wall PW-I may be removed, and a preliminary barrier wall opening OP-POI may be formed through the preliminary conductive barrier wall PW-I. During the first etching, the barrier insulating layer IP and the pixel definition layer PDL may be etched using the fourth photoresist layer PR4 as a mask.

The dry etch process to form the preliminary barrier wall opening OP-POI may be performed under an environment in which the first preliminary barrier wall layer L1-I has substantially the same etch selectivity with respect to the second preliminary barrier wall layer L2-1. Accordingly, an outer side surface of the first preliminary barrier wall layer L1-I may be substantially aligned with an outer side surface of the second preliminary barrier wall layer L2-1.

As shown in FIG. 7I, the forming of the conductive barrier wall PW may include second etching the first preliminary barrier wall layer L1-I (see, e.g., FIG. 7H) to form the first barrier wall layer L1 and the second barrier wall layer L2. The second etching may be performed by wet-etching the first preliminary barrier wall layer L1-I using the fourth photoresist layer PR4 as the mask. The etched portion of the first preliminary barrier wall layer L1-I may be removed, and the first barrier wall layer L1 and the second barrier wall layer L2 may be formed. The first barrier wall layer L1 and the second barrier wall layer L2 may be referred to as the conductive barrier wall PW. The outer barrier wall opening OP-PO may be formed through the conductive barrier wall PW.

The outer barrier wall opening OP-PO may include the first area A1 (see, e.g., FIGS. 5-6) defined by the first outer side surface OS-L1 of the first barrier wall layer L1 and the second area A2 (see, e.g., FIGS. 5-6) defined by the second outer side surface OS-L2 of the second barrier wall layer L2. The first area A1 and the second area A2 may be provided integrally as the opening. The first area A1 may have the width different from the width of the second area A2. As an example, the length in one direction of the first area A1 may be greater than the length in the one direction (e.g., the same direction) of the second area A2. The one direction may be normal (e.g., perpendicular) to the thickness direction, e.g., the third direction DR3, of the circuit element layer DP-CL. For example, the one direction may be the first direction DR1 or the second direction DR2.

In one or more embodiments, the wet etching process may be performed under an environment in which the first preliminary barrier wall layer L1-I has an etch selectivity with respect to the second preliminary barrier wall layer L2-I (see, e.g., FIG. 7H). Accordingly, the conductive barrier wall PW that defines the outer barrier wall opening OP-PO may have the undercut shape when viewed in the cross-section. For example, an etch rate of the first preliminary barrier wall layer L1-I that defines the outer barrier wall opening OP-PO with respect to an etching solution may be greater than an etch rate of the second preliminary barrier wall layer L2-I that defines the outer barrier wall opening OP-PO with respect to the etching solution, and thus, the first preliminary barrier wall layer L1-I may be mainly etched. Accordingly, the first outer side surface OS-L1 of the first barrier wall layer L1 may be recessed inwardly with respect to the second outer side surface OS-L2 of the second barrier wall layer L2 toward the anode AE. The tip portion may be formed in the conductive barrier wall PW by the portion of the second barrier wall layer L2, which is protruded outward with respect to the first barrier wall layer L1.

Referring to FIG. 7J, the manufacturing method of the display panel may include the forming of the light emitting pattern EP that covers the first electrode AE and a portion of the conductive barrier wall PW after removing the fourth photoresist layer PR4 (see, e.g., FIG. 7I).

The forming of the light emitting pattern EP may include a deposition process of the light emitting layer. The deposition process of the light emitting layer may be a thermal evaporation process, however, this is merely an example. The deposition process of the light emitting layer should not be limited thereto or thereby. The light emitting layer may be divided into portions by the tip portion formed in the conductive barrier wall PW, and the light emitting pattern EP and a first dummy layer D1 may be formed. The light emitting pattern EP may be formed to cover the side surface of the barrier insulating layer IP and the side surface of the second barrier wall layer L2, and the first dummy layer D1 may be formed on the common electrode BE.

For example, the first dummy layer D1 spaced and/or apart (e.g., spaced apart or separated) from the light emitting pattern EP may be formed together with the light emitting pattern EP. The first dummy layer D1 may include an organic material. As an example, the first dummy layer D1 may include the same material as the light emitting pattern EP. The first dummy layer D1 may be substantially concurrently (e.g., substantially simultaneously) formed with the light emitting pattern EP through a single process and may be separated from the light emitting pattern EP by the undercut shape of the outer barrier wall opening OP-PO.

Then, the manufacturing method of the display panel may include the forming of the second electrode CE, which is electrically connected to the conductive barrier wall PW, on the light emitting pattern EP.

The forming of the cathode CE may include a deposition process of a cathode layer. The deposition process of the cathode layer may be a thermal evaporation process; however, this is merely an example. The deposition process of the cathode layer should not be limited thereto or thereby. The cathode layer may be separated into portions by the tip portion formed in the conductive barrier wall PW, and the cathode CE and a second dummy layer D2 may be formed. The cathode CE may be formed to cover the upper surface of the light emitting pattern EP and at least a portion of the side surface of the light emitting pattern EP, and the second dummy layer D2 may be arranged on the first dummy layer D1.

For example, the second dummy layer D2 separated from the cathode CE may be formed with the cathode CE during the forming of the cathode CE. The second dummy layer D2 may include a conductive material. As an example, the second dummy layer D2 may include the same material as the cathode CE. The second dummy layer D2 may be substantially concurrently (e.g., substantially simultaneously) formed with the cathode CE through a single process and may be separated from the cathode CE by the undercut shape of the outer barrier wall opening OP-PO.

The anode AE, the light emitting pattern EP, and the cathode CE may be sequentially stacked in the third direction DR3. The anode AE, the light emitting pattern EP, and the cathode CE may form the light emitting element ED. The first dummy layer D1 and the second dummy layer D2 may be sequentially stacked in the third direction DR3.

Referring to FIG. 7K, the manufacturing method of the display panel may include forming the auxiliary electrode SE that covers the second electrode CE.

The forming of the auxiliary electrode SE may include a deposition process for an auxiliary electrode layer. The deposition process for the auxiliary electrode layer may be a sputtering process; however, this is merely an example. The deposition process for the auxiliary electrode layer should not be limited thereto or thereby.

The auxiliary electrode layer may include the conductive material. As an example, the conductive material may include a metal, a transparent conductive oxide (TCO), and/or one or more (e.g., any suitable) combinations thereof. As an example, the metal may include gold (Au), silver (Ag), aluminum (Al), magnesium (Mg), lithium (Li), molybdenum (Mo), titanium (Ti), copper (Cu), and/or alloys thereof. The transparent conductive oxide may include indium tin oxide (ITO), indium zinc oxide (IZO), zinc oxide, indium oxide, indium gallium oxide, indium gallium zinc oxide (IGZO), or aluminum zinc oxide.

The auxiliary electrode SE may cover the second electrode CE (or the cathode) and may be directly in contact with the conductive barrier wall PW to electrically connect the conductive barrier wall PW and the second electrode CE. The auxiliary electrode SE may be in contact with the lower surface B-L2 (see, e.g., FIG. 5) of the second barrier wall layer L2 and the first outer side surface OS-L1 of the first barrier wall layer L1. As an example, the auxiliary electrode SE may cover the cathode CE and may extend along the lower surface B-L2 of the second barrier wall layer L2 and the first outer side surface OS-L1 (see, e.g., FIG. 5) of the first barrier wall layer L1. However, this is merely an example, and the shape of the auxiliary electrode SE should not be limited thereto or thereby. In one or more embodiments, the auxiliary electrode SE may include the portion covering the cathode CE and the lower surface B-L2 of the second barrier wall layer L2 and the portion that is in contact with the first outer side surface OS-L1 of the first barrier wall layer L1 without extending from the lower surface B-L2 of the second barrier wall layer L2.

Referring to FIGS. 7L and 7M, the manufacturing method of the display panel may include forming the lower encapsulation inorganic pattern LIL that covers the auxiliary electrode SE. The forming of the lower encapsulation inorganic pattern LIL may include depositing a lower encapsulation inorganic layer LIL-I and removing a portion of the lower encapsulation inorganic layer LIL-I, which does not overlap the light emitting element ED.

Referring to FIG. 7L, the forming of the lower encapsulation inorganic pattern LIL (see, e.g., FIG. 7M) may include depositing the lower encapsulation inorganic layer LIL-I. The lower encapsulation inorganic layer LIL-I may be formed through the deposition process. The lower encapsulation inorganic layer LIL-I may be formed through a chemical vapor deposition (CVD) process. The lower encapsulation inorganic layer LIL-I may be formed to cover the auxiliary electrode SE.

Referring to FIG. 7M, the forming of the lower encapsulation inorganic pattern LIL may include forming a fifth photoresist layer PR5 and removing a portion of the lower encapsulation inorganic layer LIL-I (see, e.g., FIG. 7L), which does not overlap the light emitting element ED.

The fifth photoresist layer PR5 may be formed by forming a preliminary photoresist layer and patterning the preliminary photoresist layer using a photomask. The fifth photoresist layer PR5 may be formed in a pattern corresponding to the light emitting element ED through the patterning process.

The portion of the lower encapsulation inorganic layer LIL-I, which does not overlap the light emitting element ED, may be removed by dry-etching the lower encapsulation inorganic layer LIL-I using the patterned fifth photoresist layer PR5 as a mask. The lower encapsulation inorganic pattern LIL that overlaps the light emitting element ED may be formed from the patterned lower encapsulation inorganic layer LIL-I.

The manufacturing method of the display panel may further include removing the dummy layers D1 and D2 (see, e.g., FIG. 7L) to form the dummy area. The second dummy layer D2 of the dummy layers D1 and D2 may be removed by a wet etching process, and the first dummy layer D1 of the dummy layers D1 and D2 may be removed by a strip process. In this case, as the dummy layers D1 and D2 are removed, the lower encapsulation inorganic pattern LIL may be spaced and/or apart (e.g., spaced apart or separated) from the common electrode BE when viewed in the cross-section. The area where the lower encapsulation inorganic pattern LIL is spaced and/or apart (e.g., spaced apart or separated) from the common electrode BE when viewed in the cross-section may be referred to as the dummy area.

Referring to FIG. 7N, the manufacturing method of the display panel may include forming the encapsulation organic layer OL and the upper encapsulation inorganic layer UIL to complete the display panel DP after removing the fifth photoresist layer PR5 (see, e.g., FIG. 7M). The encapsulation organic layer OL may be formed by coating the organic material using an inkjet method; however, the present disclosure should not be limited thereto or thereby. The encapsulation organic layer OL may provide a flat upper surface. The dummy area may be filled with the encapsulation organic layer OL; however, the present disclosure should not be limited thereto or thereby. As an example, the dummy area may not be filled or may be partially filled with the encapsulation organic layer OL.

Then, the upper encapsulation inorganic layer UIL may be formed by depositing the inorganic material. Through this, the display panel DP including the base layer BL, the circuit element layer DP-CL, the display element layer DP-OLED, and the thin film encapsulation layer TFE may be formed.

A process of forming a barrier wall opening and a light emitting opening, which correspond to a light emitting area of other colors, through the conductive barrier wall PW and the pixel definition layer PDL, a process of forming light emitting elements providing other colors, and a process of forming auxiliary electrodes covering the light emitting elements providing other colors and the lower encapsulation inorganic pattern covering the auxiliary electrodes may be further performed between the forming of the lower encapsulation inorganic pattern LIL and the completing of the display panel DP. Accordingly, the display panel DP that includes the first, second, and third light emitting elements ED1, ED2, and ED3, the first, second, and third auxiliary electrodes SE1, SE2, and SE3, and the first, second, and third lower encapsulation inorganic patterns LIL1, LIL2, and LIL3 as shown in FIG. 6 may be formed.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The display panel, the light emitting device, the electronic apparatus, a device for manufacturing thereof, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. In addition, it is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display panel comprising:
a circuit element layer comprising a transistor;
a common electrode on the circuit element layer;
a conductive barrier wall on the common electrode and defining an outer barrier wall opening and an inner barrier wall opening;
a barrier insulating layer on the conductive barrier wall;
a first electrode on the barrier insulating layer and in the inner barrier wall opening and electrically connected to the transistor;
a light emitting pattern on the first electrode and covering a portion of the conductive barrier wall and the barrier insulating layer; and
a second electrode covering the light emitting pattern and electrically connected to the conductive barrier wall, wherein the inner barrier wall opening of the conductive barrier wall overlaps a center of the light emitting pattern.

2. The display panel of claim 1, wherein the inner barrier wall opening has a polygonal shape.

3. The display panel of claim 1, wherein the inner barrier wall opening has a circular shape.

4. The display panel of claim 1, wherein the conductive barrier wall comprises:
a first barrier wall layer on the common electrode; and
a second barrier wall layer on the first barrier wall layer.

5. The display panel of claim 4, wherein the first barrier wall layer comprises a first inner side surface, the second barrier wall layer comprises a second inner side surface, and the first inner side surface and the second inner side surface define the inner barrier wall opening and are aligned with each other.

6. The display panel of claim 4, wherein the outer barrier wall opening comprises:
a first area defined by a first outer side surface of the first barrier wall layer; and
a second area defined by a second outer side surface of the second barrier wall layer, a length in a first direction of the first area is greater than a length in the first direction of the second area, and the first direction is perpendicular to a thickness direction of the circuit element layer.

7. The display panel of claim 6, wherein the light emitting pattern covers at least a portion of the second outer side surface of the second barrier wall layer.

8. The display panel of claim 6, further comprising an auxiliary electrode that covers the second electrode and is directly in contact with the conductive barrier wall.

9. The display panel of claim 8, wherein the auxiliary electrode covers a lower surface of the second barrier wall layer.

10. The display panel of claim 8, wherein the auxiliary electrode is in contact with the first outer side surface of the first barrier wall layer.

11. The display panel of claim 8, wherein the auxiliary electrode is electrically connected to the conductive barrier wall and the second electrode.

12. The display panel of claim 8, further comprising a lower encapsulation inorganic pattern that covers the auxiliary electrode, wherein the lower encapsulation inorganic pattern is spaced from the common electrode when viewed in a cross-section.

13. The display panel of claim 1, further comprising a pixel definition layer on the barrier insulating layer and defining a light emitting opening therethrough to expose at least a portion of the first electrode, wherein the light emitting opening overlaps the inner barrier wall opening.

14. A method of manufacturing a display panel, the method comprising:
forming a circuit element layer comprising a transistor and a common electrode on a base layer;
forming a preliminary conductive barrier wall on the common electrode;
forming an inner barrier wall opening through the preliminary conductive barrier wall;
forming a barrier insulating layer on the preliminary conductive barrier wall and in the inner barrier wall opening;
forming a first electrode electrically connected to the transistor on the barrier insulating layer and in the inner barrier wall opening;
forming a pixel definition layer covering the first electrode and on the barrier insulating layer;
etching the preliminary conductive barrier wall to form a conductive barrier wall defining an outer barrier wall opening;
forming a light emitting pattern covering the first electrode and a portion of the conductive barrier wall; and
forming a second electrode electrically connected to the conductive barrier wall on the light emitting pattern.

15. The method of claim 14, wherein the forming of the inner barrier wall opening through the preliminary conductive barrier wall comprises etching the preliminary conductive barrier wall to define the inner barrier wall opening to have a polygonal shape or a circular shape.

16. The method of claim 14, wherein the forming of the preliminary conductive barrier wall on the common electrode comprises:
forming a first preliminary barrier wall layer on the common electrode; and
forming a second preliminary barrier wall layer on the first preliminary barrier wall layer, and the forming of the inner barrier wall opening through the preliminary conductive barrier wall comprises etching the preliminary conductive barrier wall so that a first inner side surface of the first preliminary barrier wall layer is aligned with a second inner side surface of the second preliminary barrier wall layer.

17. The method of claim 16, wherein the etching of the preliminary conductive barrier wall to form the conductive barrier wall defining the outer barrier wall opening comprises:
first etching the first preliminary barrier wall layer and the second preliminary barrier wall layer; and
second etching the first preliminary barrier wall layer to form a first barrier wall layer and a second barrier wall layer.

18. The method of claim 14, further comprising forming an auxiliary electrode that covers the second electrode, is directly in contact with the conductive barrier wall, and electrically connects the conductive barrier wall and the second electrode.

19. The method of claim 18, further comprising forming a lower encapsulation inorganic pattern that covers the auxiliary electrode and is spaced from the common electrode when viewed in a cross-section.

20. An electronic apparatus comprising:
a circuit element layer comprising a transistor;
a common electrode on the circuit element layer;
a conductive barrier wall comprising a first barrier wall layer on the common electrode and a second barrier wall layer on the first barrier wall layer, and defining an outer barrier wall opening and an inner barrier wall opening therethrough;
a first electrode on the conductive barrier wall and in the inner barrier wall opening and electrically connected to the transistor through the inner barrier wall opening;
a light emitting pattern on the first electrode and covering a portion of the second barrier wall layer;
a second electrode covering the light emitting pattern; and
an auxiliary electrode covering the second electrode and being in contact with a lower surface of the second barrier wall layer and a first outer side surface of the first barrier wall layer, wherein the outer barrier wall opening surrounds the inner barrier wall opening when viewed in a plan view of the display panel, and the auxiliary electrode is electrically connected to the conductive barrier wall and the second electrode.
